(19) United States
(12) Patent Application Publication
(10) Pub. No.: US 2026/0011378 A1
(43) Pub. Date: Jan. 8, 2026

(54) MULTI-LEVEL THERMOMETER ENCODING FOR MULTI-BIT CELL NAND MEMORY SEARCH

(71) Applicant: MACRONIX INTERNATIONAL CO., LTD., HSINCHU (TW)

(72) Inventor: Po-Hao TSENG, TAICHUNG (TW)

(73) Assignee: MACRONIX INTERNATIONAL CO., LTD., HSINCHU (TW)

(21) Appl. No.: 19/022,241

(22) Filed: Jan. 15, 2025

Related U.S. Application Data
(60) Provisional application No. 63/667,152, filed on Jul. 3, 2024.

(51) Int. Cl. G11C 16/26; G11C 16/04; G11C 16/08

(52) U.S. Cl. CPC G11C 16/26; G11C 16/0483; G11C 16/08

(57) ABSTRACT

A 3D search engine receives searches for application to word lines of a nonvolatile memory array. Features are stored and searched in accordance with a multi-level thermometer encoding enabling use of multi-bit cell NAND technology, such as MLC, TLC, and QLC. The engine uses two word lines per digit of information of the searches and two memory devices per digit of stored feature to search against. The engine uses respective bit lines of the nonvolatile memory array as respective match lines for searching. Respective memory strings (e.g., NAND memory strings) of the nonvolatile memory array are usable to store respective data words, e.g., corresponding to features to search for. Respective pluralities of the memory strings are coupled in parallel to respective shared bit lines. The engine determines matches according to degree of similarity, such as high to low. The engine is applicable to searching, comparing, and sorting.

### RELATED APPLICATION

This application claims priority under 35 U.S.C. § 119 (e) to U.S. Provisional Application No. 63/667,152, entitled “MULTI-LEVEL THERMOMETER CODING FOR 3D-NAND AI SEARCH ENGINE”, filed on Jul. 3, 2024, which is incorporated by reference herein for all purposes.

### BACKGROUND

### Field

This disclosure relates to encoding for In-Memory Approximate Searching (IMAS), implementable using NAND memory (e.g., 3D NAND memory) and as applicable to big data and/or Artificial Intelligence (AI) processing.

### Description of Related Art

Growth of big data and AI (such as AI hardware accelerators) are increasing the importance of searching, comparing, and/or sorting data. Conventional systems implement concurrent searching using Ternary Content Addressable Memory (TCAM) technology.

Conventional TCAM technology is implementable using Static Randomly Accessible read/write Memory (SRAM) techniques, and thus has relatively low memory density (such as 16 transistors to form a single TCAM cell) and relatively high power usage.

Recently proposed TCAM technology is implementable using nonvolatile memory techniques, such as based on two transistor two resistor (2T2R) techniques and two ferroelectric field-effect transistor (2FeFET) techniques. However, the nonvolatile-implemented TCAM techniques require paired memory for a single TCAM cell (or paired memory cells to implement one search bit or one data bit) and therefore efficiency of searching and data storage is limited.

Example techniques using NAND-flash-based In-Memory Searching (IMS) functions enabled to perform exact matching and approximate matching operations are described in P. H. Tseng et al., In-Memory-Searching Architecture Based on 3D-NAND Technology with Ultra-high Parallelism, 2020 IEDM; and P. H. Tseng et al., In-Memory Approximate Computing Architecture Based on 3D-NAND Flash Memories, 2022 VLSI.

However, additional techniques are needed that enable higher performance searching, comparing, and/or sorting, such as relating to big data and/or AI processing.

### SUMMARY

A system of one or more computers is configurable to perform particular operations or actions by virtue of having software, firmware, hardware, or a combination of them installed on the system that in operation causes or cause the system to perform the actions. One or more computer programs are configurable to perform particular operations or actions by virtue of including instructions that, when executed by data processing apparatus, cause the apparatus to perform the actions.

A system of one or more computers is configurable to perform particular operations, actions, and/or functions by virtue of having software, firmware, hardware, or a combination of them installed on the system that in operation causes or cause the system to perform the operations, actions, and/or functions. One or more computer programs is configurable to perform particular operations, actions, and/or functions by virtue of including instructions that, when executed by data processing apparatus, cause the apparatus to perform the operations, actions, and/or functions. An aspect includes a computing system that includes a memory that optionally includes a plurality of memory strings, each coupled to a match line coupled to a sense amplifier and a source line, and each memory string optionally includes a plurality of series-connected devices, each having and being responsive to a configured state that is one of three or more mutually exclusive state values and a respective control input; and a plurality of word lines, each coupled to a respective control input of the respective control inputs. The system also includes a search encoder enabled to receive a search and drive the word lines according to a search encoding, where each memory string is enabled to couple the match and the source lines via an impedance responsive to an amount of a match between the configured states of the memory string and the control inputs of the series-connected devices, and the sense amplifier is enabled to generate a respective indication of the amount of the match indicated by the impedance. Other aspects include corresponding computer systems, apparatus, and computer programs recorded on one or more computer storage devices, each configured to perform actions of the system.

Implementations optionally include one or more of the following features. The computing system where the search encoding optionally includes a multi-level thermometer search encoding. The multi-level search encoding uses a plurality of digits each having a respective digit value that is one of N mutually exclusive digit values, and there are N mutually exclusive state values, N being an integer that is greater than 2. The word lines are operated in pairs according to the multi-level thermometer search encoding and the configured states are managed in pairs according to a multi-level thermometer feature encoding. Responsive to the impedance being a match-found impedance, the respective indication of the amount of the match indicated by the impedance is a match-found indication. The series-connected devices optionally include series-connected floating-gate transistors, each of the configured states corresponds to a respective threshold voltage that the series-connected floating-gate transistors are enabled to operate in accordance with, and each of the respective control inputs is coupled to a respective gate of one more of the series-connected floating-gate transistors. Implementations of the described techniques optionally include hardware, a method or process, or computer software on a computer-accessible medium.

An aspect includes a method that includes receiving a search request encoded according to a thermometer code having a plurality of search digits, each enabled to represent one of more than two distinct values; responsive to the search request, determining whether a memory array having a plurality of In Memory Approximate Search (IMAS) cells has stored, within a subset of the IMAS cells, a feature matching the search request, each enabled to store a respective digit of the stored feature, each enabled to represent a respective one of more than two distinct values; and indicating a result of the determining. Other aspects include corresponding computer systems, apparatus, and computer programs recorded on one or more computer storage devices, each configured to perform actions of the system.

Implementations optionally include one or more of the following features. The method where each of the IMAS cells optionally include a pair of floating-gate transistors in series, each operable according to more than two distinct threshold voltages, and the determining optionally includes applying word line voltages to control gates of the floating-gate transistors according to the more than two distinct threshold voltages. The search request is an encoded search request and optionally includes receiving an unencoded search request and in dependence thereon producing the encoded search request. The indicating of the result optionally includes indicating a selected one of (a) a match between the search request and a stored feature matching the search request and (b) no match between the search request and any feature stored in the memory array. The indicating of the result optionally includes indicating an approximate match between the search request and the stored feature matching the search request. The IMAS cells correspond to at least one of a Multi-Level Cell (MLC) flash storage technology and a Tri-Level Cell (TLC) flash storage technology. Implementations of the described techniques optionally include hardware, a method or process, or computer software on a computer-accessible medium.

An aspect includes a computing system that includes interface circuitry to enable a host agent to provide a search and to receive one or more results of the search; a plurality of memory strings each receiving a respective set of word lines having voltages determinable responsive to the search from and selected from a set of more than three word line voltage values; a plurality of sense amplifiers each coupled to a corresponding one of the memory strings; and priority encoder circuitry enabled to receive match indications from the sense amplifiers, and where the sense amplifiers are enabled to determine, with respect to matches between feature information stored in the memory strings coupled to the sense amplifier and the word lines received by the memory strings coupled to the sense amplifier, that there are no matches and there is at least one match, and where the priority encoder circuitry, based on the determinations of the sense amplifiers, is enabled to indicate at least a portion of the results as a highest priority match of any matches identified by the sense amplifiers. Other aspects include corresponding computer systems, apparatus, and computer programs recorded on one or more computer storage devices, each configured to perform actions of the system.

Implementations optionally include one or more of the following features. The computing system optionally includes a multi-level thermometer search encoder to determine the word line voltages responsive to the search. The computing system optionally includes the host agent. The priority encoder circuitry, based on the determinations of the sense amplifiers, is enabled to indicate at least a portion of the results as a second highest priority match of any matches identified by the sense amplifiers. The feature information is stored in the memory strings by configuring threshold voltages of floating-gate transistors of the memory strings in dependence on encoding results of the multi-level thermometer feature encoder. A feature encoding is used to encode at least some of the feature information and a search encoding is used to encode at least a portion of the search. The feature encoding is a multi-level thermometer encoding compatible with the memory strings operating in accordance with threshold voltages set in accordance with more than two threshold voltages. The computing system is part of a System-On-a-Chip (SOC). Implementations of the described techniques optionally include hardware, a method or process, or computer software on a computer-accessible medium.

### BRIEF DESCRIPTION OF THE DRAWINGS

FIGS. 1A-1C collectively illustrate various aspects of an example 3D (search) engine, such as a NAND-based 3D (search) engine incorporating multi-level thermometer encoding for multi-bit cell NAND memory search techniques.

FIGS. 2A-2E collectively illustrate an example multi-level thermometer encoding for a 3D (search) engine using Multi-Level Cell (MLC) technology.

FIG. 3 illustrates an example MLC-based 2D (search) Engine.

FIG. 4 illustrates usage examples for a 3D (search) engine using Multi-Level Cell (MLC) technology.

FIGS. 5A-5E collectively illustrate an example multi-level thermometer encoding for a 3D (search) engine using Tri-Level Cell (TLC) technology.

FIG. 6 illustrates an example TLC-based 2D (search) Engine.

FIG. 7 illustrates usage examples for a 3D (search) engine using Tri-Level Cell (TLC) technology.

FIG. 8 illustrates an example operating flow for a 3D (search) engine.

FIG. 9 illustrates an example 3D engine appliance comprising an example 3D engine device.

FIG. 10 illustrates an example hardware system having a 3D (search) Engine.

FIGS. 11A, 11B, and 11C each illustrate a respective example of a multi-level thermometer encoding for multi-bit cell NAND feature memory storing and searching.

### DETAILED DESCRIPTION

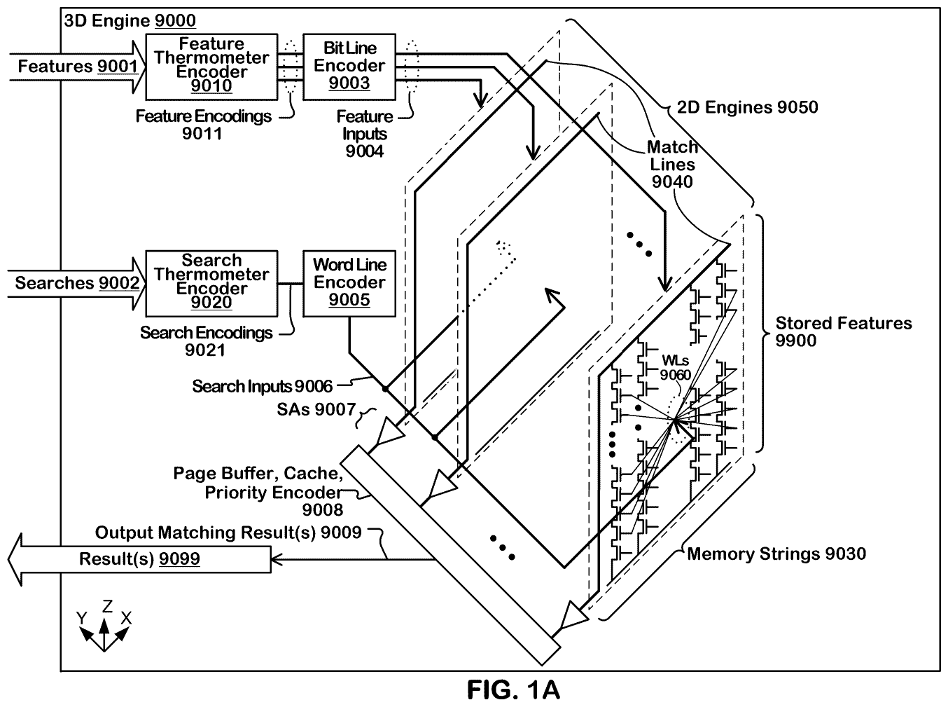

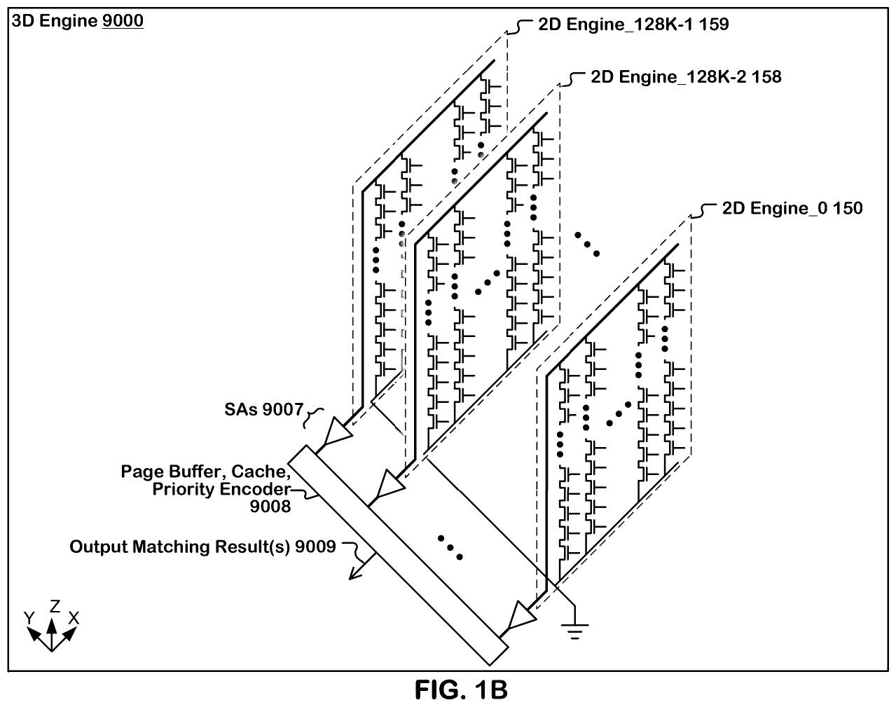

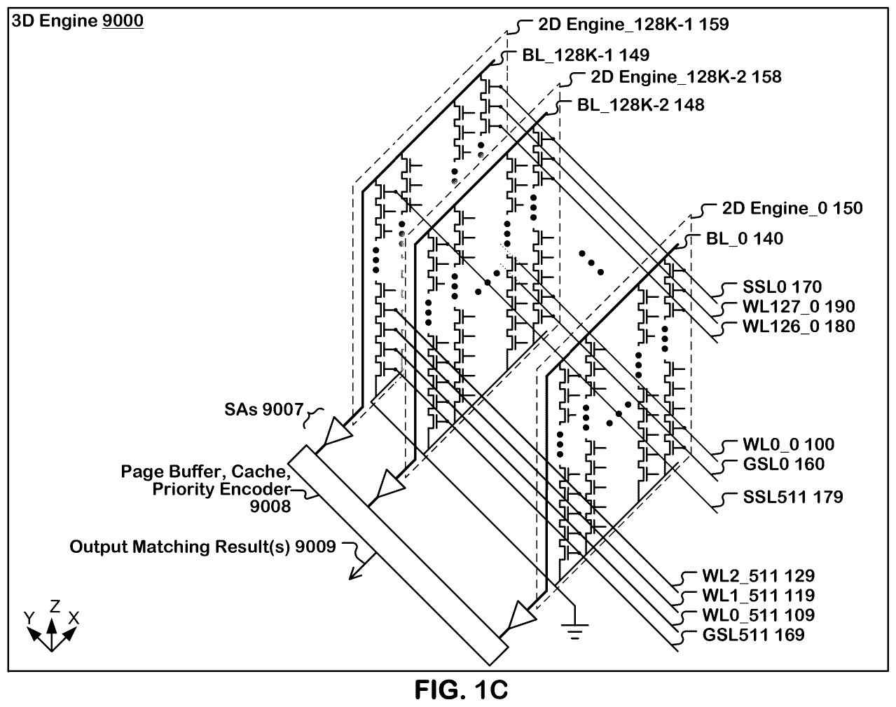

A detailed description of techniques relating to architecture for a 3D search engine, such as using multi-level thermometer encoding for multi-bit cell NAND memory technology, is provided with reference to FIGS. 1A-1C, 2A-2E, 3, 4, 5A-5E, 6-10, and 11A-11C. Using multi-level thermometer encoding for multi-bit cell NAND memory technology enables, in some scenarios, an increase in NAND array efficiency (e.g., for big data uses, such as large database storage) by reducing a number of devices in series in NAND units used to store and search against quantized data.

Multi-level thermometer encoding is usable for approximate matching between searches and stored features. A best match (e.g., high similarity) has a highest memory string current (e.g., lowest impedance). A worst match (e.g., low similarity) has a lowest memory string current (e.g., highest impedance). A number of digits matched (or mismatched) is determinable by measurement of memory string current and/or impedance.

One or more flow diagrams are described herein. Processing described by the flow diagrams is implementable and/or directable using processors programmed using computer programs stored in memory accessible to computer systems and executable by the processors, using dedicated logic hardware (including field programmable integrated circuits), and using various combinations thereof. Various actions are combinable, performable in parallel, and/or performable in a different sequence without affecting processing achieved. In some cases, a rearrangement of actions achieves identical results only if certain other changes are made as well. In other cases, a rearrangement of actions achieves identical results only if certain conditions are satisfied. Furthermore, for clarity, some of the flow diagrams herein omit certain some actions not necessary for understanding the disclosed techniques. Various additional actions are performable before, after, and/or between the illustrated actions.

Examples of selected acronyms, mnemonics, and abbreviations used in the description are as follows.

An example of a number system is a base-N number system. In a base-N number system, digits are used that each enable representation of one of N mutually exclusive states, such as by quantization to one of N corresponding values. As a specific example, in a base-2 number system, a binary digit (“bit” for short) is enabled to represent any one of two mutually exclusive states (e.g., one of zero (“0”) or one (“1”)) quantized to one of two corresponding values. As another a specific example, in a base-4 number system, a quaternary digit is enabled to represent any one of four mutually exclusive states (e.g., one of zero (“0”), one (“1”), two (“2”), or three (“3”)) quantized to one of four corresponding values. Other specific examples include a base-8 number system using octal digits quantized to one of eight values and a base-16 number system using hexadecimal digits quantized to one of 16 values.

An example of encoding is unary encoding, such as representing a natural number with a code length of one more than the value of the natural number. An example of unary encoding is single-level thermometer encoding. An example single-level thermometer encoding is one or more zero (“0”) digits followed by one or more one (“1”) digits. For example, three (“3”) can be represented by 16 digits, 13 zero digits followed by three one digits, e.g., “0000_0000_0000_0111” (for readability, the 7-bit value is separated at four bits by an underscore (“_”) character). For another example, six can be represented by 16 digits, 10 zero digits followed by six one digits, e.g., “0000_0000_0011_1111”.

Multi-level thermometer encoding, which can have more variations than single-level thermometer encoding as described above, can use additional digit values, such as two (“2”) and three (“3”), in addition to zero (“0”) and one (“1”), thus having four mutually exclusive digit values, “0”-“3”. For example, three (“3”) can be represented by five digits, two “0” digits followed by three “1” digits, e.g., “00111”. For another example, six can be represented by five digits, a “2” digit followed by four “1” digits, e.g., “21111”. Another example of multi-level thermometer encoding can use further additional digit values, such as four (“4”) through seven (“7”), in addition to zero (“0”) through three (“3”). For example, three can be represented by two digits, a “2” digit followed by a “1” digit, e.g., “21”. For another example, six can be represented by two digits, both “3” digits, e.g., “33”. In some contexts, single-level thermometer encoding and/or multi-level thermometer encoding are referred to as expansion encoding.

In some scenarios, the sum of the digits of a multi-level thermometer encoding indicates the corresponding value, enabling rearranging stored digits and/or search digits while retaining identical corresponding values. For example, the sum of the digits of the multi-level thermometer encoding “00111” is three and corresponds to the encoded value three (“3”). Thus, an alternate multi-level encoding for the value three (“3”) is “01110”. For another example, the sum of the digits of the multi-level thermometer encoding “21” is three and corresponds to the encoded value three (“3”).

An example of a memory device is an element enabled to store information to indicate one of at least two mutually exclusive states of the memory device. The states are settable (e.g., placed in a configured state) via programming the memory device and are readable via activating a control input of the memory device. In some types of memory devices, e.g., floating-gate memory devices, the programming is via configuring a threshold voltage of the memory device. The configuring is exemplified by programming the memory device (e.g., to a “0”, “1”, “2”, “3”, or some other appropriate value), also referred to as storing a value (e.g., a “0”, “1”, “2”, “3”, or some other appropriate value).

Memory devices are characterizable by how much information each device is enabled to represent, such as via mutually exclusive states quantizable to corresponding values. For example, a memory device using Single-Level Cell (SLC) technology (termed, e.g., an SLC memory device) is enabled to represent any one of two mutually exclusive states quantized to one of two corresponding values and is thus usable to represent a single base-2 digit. For another example, a memory device using Multi-Level Cell (MLC) technology (termed, e.g., an MLC memory device) is enabled to represent any one of four mutually exclusive states quantized to one of four corresponding values and is thus usable to represent a single base-4 digit. Other examples include memory devices using Triple-Level Cell (TLC) memory technology quantized to one of eight values to represent a single base-8 digit, memory devices using Quad-Level Cell (QLC) memory technology quantized to one of 16 values to represent a single base-16 digit, and any other multi-bit NAND memory techniques such that a memory device is enabled to represent more than two mutually exclusive states.

An example of a NAND memory is a Not AND memory, e.g., series connection of devices forming a memory string memory. An example of a memory string is a series-connected plurality of memory devices. An example of an IMAS cell is a pair of series-connected memory devices, such as pairs of memory devices of a memory string. An example terminus for a memory string is a Bit Line (BL), such as coupled to a Sense Amplifier (SA). Another example terminus of a memory string is a Common Source Line (CSL). An IMAS cell is enabled to store a digit of a feature and to compare the stored feature digit with a received search input digit. An example of an SA is a circuit enabled to resolve a relatively small analog signal (e.g., a current or a voltage) or a change thereof, into a full-swing digital signal.

### 3D (Search) Engine Concepts

Disclosed herein is a 3D search engine architecture implementable using 3D-NAND memory that enables high performance searching, comparing, and/or sorting, such as relating to big data and/or AI processing. The architecture provides for low latency, high resolution, high content density, multi-block functionality, and robust reliability. The architecture is applicable to various fields such as big-data searching, AI hardware accelerators and/or classifiers, approximate computing, associative memory, few-shot learning, Solid-State Disk (SSD) data management, DeoxyriboNucleic Acid (DNA) matching, data filtering, hyper-dimensional computing, as well as other applications benefiting from IMAS enabled for long search words and large data capacities. Since the architecture enables high performance comparing and sorting, as well as searching, the term “search” is parenthetical as in “3D (search) engine” as well as in “2D (search) engine”.

A 3D (search) engine receives searches for application to word lines (WLs) of a nonvolatile memory array. The 3D (search) engine uses two word lines per digit of information of the searches. The 3D (search) engine uses respective bit lines of the nonvolatile memory array as respective matching lines for searching. Respective memory strings (e.g., NAND memory strings) of the nonvolatile memory array are usable to store respective data words, e.g., corresponding to features to search for. Respective pluralities of the memory strings are coupled in parallel to respective shared bit lines.

In some usage scenarios, read latency of a 3D (search) engine is reduced (at the potential expense of a relatively large current transient) by operating multiple blocks concurrently. The concurrent operating is via switching a plurality of activation controls, e.g., string select lines (SSLs).

A 3D (search) engine has specific applicability to big data and/or AI, such as for various searching, comparing, and/or sorting operations. A host agent directs storage of features in the 3D (search) engine and then provides searches to the 3D (search) engine to determine matches to the stored features. Indications of the matches are returned to the host agent.

A 3D (search) engine uses a plurality of 2D (search) engines to perform operations concurrently across the 2D (search) engines and can be referred to as a “Search Cube” or simply a “Cube”. The 3D (search) engine is enabled to perform a plurality of searches concurrently using a plurality of search parameters across a plurality of stored features. In some usage contexts, the concurrent searching is per 2D (search) engine. For instance, each 2D (search) engine is tasked with a unique search operation. In some usage contexts, the concurrent searching is within a particular 2D (search) engine. For instance, different portions of the particular 2D (search) engine are tasked with a unique search operation. In some usage contexts, the concurrent searching is parallelized across a plurality of 2D (search) engines and within one or more of the 2D (search) engines. Indications of matches between the search parameters and the stored features are provided by the 2D (search) engines for processing. The processing includes, for example, determining an overall similarity between the search parameters and the stored features and/or identifying which one or more stored features that are similar compared to the search parameters, e.g., via one or more of buffering, caching, and/or priority encoding (circuitry).

Each 2D (search) engine used by the 3D (search) engine comprises a plurality of memory devices, to detect if there is a match between search information provided to the 2D (search) engines as determined from the search parameters and features stored in the 2D (search) engines. The 2D (search) engines generate match indications responsive to the detecting and provide the match indications for buffering, caching, priority encoding, and output for usage in a system. The features are stored according to a feature encoding. The search information is encoded according to a search encoding. Examples of the feature and storage encodings include multi-level thermometer encoding, such as usable with multi-bit NAND memories using, e.g., MLC, TLC, QLC, or any other multi-bit NAND memory technique such that a memory device is enabled to represent more than two mutually exclusive states. The 3D (search) engine is enabled to selectively perform exact and approximate matching, such as according to storage and/or feature encoding. An exact match corresponds to all digits matching, such as all digits of search parameters matching all digits of a value stored in a memory string. An approximate match corresponds to less than all digits matching, such as all but one digit matching, all but two digits matching, or alternatively a fraction of the digits matching, such as 90% of the digits matching (e.g., 9 out of 10 digits matching).

A control agent of the 3D (search) engine selectively operates the 2D (search) engines concurrently. The concurrent operation enables concurrent match determinations against a same set of search information provided to the 2D (search) engines operating concurrently. Each 2D (search) engine generates a match indication according to the search information and the features stored in the 2D (search) engine. A priority encoder of the 3D (search) engine processes the match indications to determine relative matching between the 2D (search) engines and/or within one or more of the 2D (search) engines.

A 2D (search) engine has a number of memory strings enabled to operate concurrently. The memory strings of a 2D (search) engine are coupled in parallel between a match line and a source line of the 2D (search) engine. Each of the memory strings is usable to store one or more respective features, each feature having one or more digits and stored according to a selected one of the feature encodings. Each of the memory strings is usable to compare one or more (encoded) search inputs with one or more (encoded) features stored in the memory string. Prior to searching, the control agent performs pair-wise programming of the features into the memory devices according to the selected feature encoding. The pair-wise programming is according to using a series-connected pair of the memory devices (e.g., an IMAS cell) for each digit of a feature. For searching, the control agent drives the control inputs in pairs, according to the search information and according to the selected search encoding. The search information comprises a search pattern and optional parameters. Results of the searching are provided as a plurality of match indications that are then optionally buffered, cached, and/or priority encoded.

### 3D (Search) Engine Example Implementation

An example 3D (search) engine implementation uses floating-gate transistors as memory devices. The floating-gate transistors are instantiated in NAND series-coupled memory strings. Thus, the 3D (search) engine is sometimes referred to as a 3D NAND search engine or more broadly as a search system or alternatively as a computing system. The memory strings are in turn instantiated in parallel between a shared bit line and a shared source line. The memory strings coupled to a shared bit line are sometimes referred to as a 2D (search) engine or more broadly as a memory.

The floating-gate transistors are programmed to store digits of features according to a plurality of mutually exclusive states, such as two mutually exclusive states (SLC technology), four mutually exclusive states (TLC technology), eight mutually exclusive states (MLC technology), or 16 mutually exclusive states (QLC technology). The programming configures the threshold voltages of the floating-gate transistors. The programmed floating-gate transistors are conditionally responsive (e.g., via an impedance change) to indicate a match between a stored feature and a search provided on word lines coupled to control gates of the floating-gate transistors.

The word lines are usable to provide one or more search inputs to search for among the stored features that have been programmed into the floating-gate devices (such as floating-gate transistors) of the memory strings. Each memory string is usable to compare one or more search values provided via the word lines coupled to the memory string to the one or more stored feature that have been programmed into the memory string.

Each shared bit line is usable as a match line to indicate zero, one, or more matches between one or more search inputs respectively provided to each memory string coupled to the shared bit line and the stored features of the respective memory strings.

Match indications provided by the shared bit lines are priority encoded (e.g., according to a predetermined priority scheme) and one or more matching results are indicated to one or more other agents of a system. Thus, a plurality of 2D (search) results are combined into one or more 3D (search) results.

FIG. 1A, FIG. 1B, and FIG. 1C collectively illustrate various aspects of an example 3D (search) engine, such as a NAND-based 3D (search) engine incorporating multi-level thermometer encoding for multi-bit cell NAND memory search techniques, as 3D Engine 9000.

More specifically, FIG. 1A illustrates an overview of the example 3D (search) engine, FIG. 1B illustrates some aspects of the example 3D (search) engine of FIG. 1A in different detail, and FIG. 1C illustrates some aspects of the example 3D (search) engine of FIG. 1A in more detail.

Returning to FIG. 1A, 3D Engine 9000 comprises a plurality (e.g., 128K) of identical (or alternatively substantially similar) 2D (search) engines, as 2D Engines 9050. For clarity, any details of all but one of the 2D (search) engines are omitted.

Each of the 2D (search) engines of 2D Engines 9050 has a plurality of memory strings, represented by Memory Strings 9030, to store feature information provided to 3D Engine 9000. The stored features are represented by Stored Features 9900. Memory Strings 9030 are also used to determine matches between the stored feature information and search information provided to 3D Engine 9000 by conditionally affecting respective match lines of Match Lines 9040. For example, the conditionally affecting includes discharging a precharged value of a match line based on a match between a portion of the search inputs and a portion of the stored features.

Feature Thermometer Encoder 9010 receives Features 9001 (e.g., sourced by a host agent) provided to 3D Engine 9000. In response, Feature Thermometer Encoder 9010 generates Feature Encodings 9011 according to a selected multi-level thermometer feature encoding. Bit Line Encoder 9003 receives Feature Encodings 9011. In response, Bit Line Encoder 9003 generates, via a selected bit line encoding, Feature Inputs 9004 suitable for application to the memory strings of the 2D (search) engines to store as portions of Stored Features 9900. In some scenarios, Feature Thermometer Encoder 9010 and Bit Line Encoder 9003 are collectively implemented and/or referred to as a Feature Encoder. In some implementations, Bit Line Encoder 9003 is omitted, with Feature Encodings 9011 being suitable for direct application to the memory strings of the 2D (search) engines. Each memory string of each 2D (search) engine is enabled to store unique features, and thus Feature Inputs 9004 is represented as having unique couplings to each of the 2D (search) engines of 2D Engines 9050. The unique couplings are implementable via separate signals to each of the 2D (search) engines, a shared time-multiplexed set of shared signals (e.g., a bus), or any other suitable communication mechanism that enables each of the memory strings of each of the 2D (search) engines to store unique features.

Search Thermometer Encoder 9020 receives Searches 9002 (e.g., sourced by the host agent) provided to 3D Engine 9000. In response, Search Thermometer Encoder 9020 generates Search Encodings 9021 according to a selected multi-level thermometer search encoding. Word Line Encoder 9005 receives Search Encodings 9021. In response, Word Line Encoder 9005 generates, via a selected word line encoding, Search Inputs 9006, suitable for application to the memory strings of the 2D (search) engines of 2D Engines 9050 to determine matches (if any) between Search Inputs 9006 and Stored Features 9900. In some scenarios, Search Thermometer Encoder 9020 and Word Line Encoder 9005 are collectively implemented and/or referred to as a Search Encoder. In some implementations, digital coding is used for Search Encodings 9021. In some implementations, Word Line Encoder 9005 transforms Search Encoding 9021 into respective pairs of analog word line voltages, e.g., bias levels, such as search bias levels. Each 2D (search) engine receives identical search information, and thus Search Inputs 9006 is represented as having parallel couplings to each of the 2D (search) engines. This is in contrast with the unique couplings used for distribution of feature information for storage. The parallel couplings are implementable via separately buffered signals to each of the 2D (search) engines, a single set of coupled signals (e.g., a bus), or any other suitable communication mechanism that enables each of the 2D (search) engines to receive identical search information. Each memory device of each memory string of a particular 2D (search) engine receives a unique word line (as provided via Search Inputs 9006) as conceptually illustrated in FIG. 1A as a sampling of word lines illustrated as WLs 9060. While each 2D (search) engine receives identical search information, each of the memory strings within a 2D (search) engine receives unique search information.

Responsive to Search Inputs 9006 and based on Stored Features 9900 of each of the 2D (search) engines, each 2D (search) engine bit line (e.g., each of Match Lines 9040) provides respective match information to a respective sense amplifier of SAs 9007 to determine match indications for each of the 2D (search) engines (or alternatively, source lines of the memory strings provide match information to sense amplifiers). The match indications are then processed by Page Buffer, Cache, Priority Encoder 9008 and provided as Output Matching Result(s) 9009, and communicated, e.g., to the host agent, as Result(s) 9099.

Turning now to FIG. 1B, some aspects the example 3D (search) engine of FIG. 1A are illustrated in more detail. Elements of FIG. 1B and FIG. 1A having identical element identifiers are identical elements.

Three of the 2D (search) engines (e.g., 2D (search) Engine_0 150, 2D (search) Engine_128K−2 158, and 2D (search) Engine_128K−1 159) are illustrated as having respectively concurrently operable memory strings. As summarized with respect to FIG. 1A, 3D Engine 9000 comprises sense amplifier circuitry. There can be one sense amplifier for each 2D (search) engine, collectively SAs 9007. For clarity, three of the sense amplifiers are illustrated, each coupled to a respective one of the illustrated 2D (search) engines. 3D Engine 9000 further comprises post-sensing circuitry, collectively Page Buffer, Cache, Priority Encoder 9008 to process output(s) of each of the sense amplifiers of SAs 9007 to produce results of matching searches as Output Matching Result(s) 9009.

Each of the 2D (search) engines are illustrated in the X and Z dimensions. In some variations built as an integrated circuit based on a planar process, layers of the integrated circuit are built up in the Z dimension. The 2D (search) engines are arrayed in the Y dimension.

Turning now to FIG. 1C, some aspects the example 3D (search) engine of FIG. 1A and FIG. 1B are illustrated in more detail. Elements of FIG. 1C, FIG. 1B, and FIG. 1A having identical element identifiers are identical elements.

Each of the 2D (search) engines comprises a respective bit line. In particular, 2D (search) Engine_0 150, 2D (search) Engine_128K−2 158, and 2D (search) Engine_128K−1 159 respectively comprise BL_0 140, BL_128K−2 148, and BL_128K−1 149. Note that in FIG. 1A, the bit lines are collectively referred to as Match Lines 9040, as each bit line is usable to indicate a match between search and stored information. Each 2D (search) engine comprises a plurality of memory strings (e.g., 512 memory strings). For clarity, four of the memory strings are illustrated in each of the 2D (search) engines. Each memory string is selectively coupled to the bit line of the 2D (search) engine via a transistor controlled by a respective SSL input. The transistor and the SSL input collectively enable selectively enabling (disabling) the memory string based on activation (deactivation) of the SSL input. Each SSL input is coupled to a memory string of each of the 2D (search) engines. Thus, each SSL input enables selectively enabling (disabling) a block of the memory strings based on activation (deactivation) of the SSL input.

For instance, SSL0 170 is enabled to selectively couple a 1st memory string of 2D (search) Engine_0 150 to BL_0 140, a 1st memory string of 2D (search) Engine_128K−2 158 to BL_128K−2 148, and a 1st memory string of 2D (search) Engine_128K−1 159 to BL_128K−1 149, each via a respective transistor. SSL0 170 is also enabled to selectively couple 128K−3 1st memory strings (not illustrated) of the 2D (search) engines between 2D (search) Engine_0 150 and 2D (search) Engine_128K−2 158 respectively to the bit lines therein via respective transistors.

For another instance, SSL511 179 is enabled to selectively couple a 512th memory string of 2D (search) Engine_0 150 to BL_0 140, a 512th memory string of 2D (search) Engine_128K−2 158 to BL_128K−2 148, and a 512th memory string of 2D (search) Engine_128K−1 159 to BL_128K−1 149, each via a respective transistor. SSL511 179 is also enabled to selectively couple 128K−3 512th memory strings (not illustrated) of the 2D (search) engines between 2D (search) Engine_0 150 and 2D (search) Engine_128K−2 158 respectively to the bit lines therein via respective transistors.

Similar to the bit lines, each of the 2D (search) engines comprises a respective source line (illustrated but for clarity not identified). Each memory string is selectively coupled to the source line of the 2D (search) engine via a transistor controlled by a respective Ground Select Line (GSL) input.

Again similar to the bit lines, for instance, GSL0 160 is enabled to selectively couple the 1st memory string of 2D (search) Engine_0 150 to a source line of 2D (search) Engine_0 150, the 1st memory string of 2D (search) Engine_128K−2 158 to a source line of 2D (search) Engine_128K−2 158, and the 1st memory string of 2D (search) Engine_128K−1 159 to a source line of 2D (search) Engine_128K−1 159, each via a respective transistor. GSL0 160 is also enabled to selectively couple 128K−3 1st memory strings (not illustrated) of the 2D (search) engines between 2D (search) Engine_0 150 and 2D (search) Engine_128K−2 158 respectively to source lines therein via respective transistors. The source lines are all connected to ground.

Again similar to the bit lines, for another instance, GSL511 169 is enabled to selectively couple a 512th memory string of 2D (search) Engine_0 150 to the source line of 2D (search) Engine_0 150, a 512th memory string of 2D (search) Engine_128K−2 158 to the source line of 2D (search) Engine_128K−2 158, and a 512th memory string of 2D (search) Engine_128K−1 159 to the source line of 2D (search) Engine_128K−1 159, each via a respective transistor. GSL511 169 is also enabled to selectively couple 128K−3 512th memory strings (not illustrated) of the 2D (search) engines between 2D (search) Engine_0 150 and 2D (search) Engine_128K−2 158 respectively to the source lines therein via respective transistors.

The SSL and GSL inputs are coupled in parallel to corresponding transistors in each of a corresponding memory string in each of the 2D (search) engines. As there are 512 memory strings in each of the 2D (search) engines, there are 512 SSL inputs and 512 GSL inputs. Note that in FIG. 1C, the coupling between GSL0 160 and a transistor of 2D (search) Engine_128K−1 159 is omitted for clarity, although a dotted-line extension of GSL0 160 is illustrated.

In 3D Engine 9000, each of the memory strings is a same length of 128 floating-gate transistors (excluding the transistors that couple each memory string to a bit line and a source line). In a planar integrated circuit process implementation of 3D Engine 9000, a certain number of layers are used to implement the memory strings. As the length of the memory strings increases, so does the number of layers used to implement the memory strings. Thus, doubling the length of the memory strings doubles the layers used to implement the memory strings.

Turning now to word lines, conceptually each 2D (search) engine is coupled to a same 2D array of word lines. In the X dimension, there are 512 columns of word lines, corresponding one-to-one with each of the 512 memory strings. In the Z dimension, there are 128 rows of word lines, corresponding one-to-one with the floating-gate transistors of each of the memory strings. Thus, the 2D array of word lines is 512 columns by 128 rows or 512*128 individual word lines. Each word line couples to a single floating-gate transistor of a single memory string in each of the 2D (search) engines. Note that in FIG. 1C, the coupling between WL0_0 100 and a floating-gate transistor of 2D (search) Engine_128K−1 159 is omitted for clarity, although a dotted-line extension of WL0_0 100 is illustrated.

For instance, WL0_0 100 couples to a floating-gate transistor of the 1st memory string of 2D (search) Engine_0 150, a floating-gate transistor of the 1st memory string of 2D (search) Engine_128K−2 158, and a floating-gate transistor of the 1st memory string of 2D (search) Engine_128K−1 159. WL0_0 100 also couples to a floating-gate transistor in each of the 128K−3 1st memory strings (not illustrated) of the 2D (search) engines between 2D (search) Engine_0 150 and 2D (search) Engine_128K−2 158.

For another instance, WL0_511 109 couples to a floating-gate transistor of the 512th memory string of 2D (search) Engine_0 150, a floating-gate transistor of the 512th memory string of 2D (search) Engine_128K−2 158, and a floating-gate transistor of the 512th memory string of 2D (search) Engine_128K−1 159. WL0_511 109 also couples to a floating-gate transistor in each of the 128K−3 512th memory strings (not illustrated) of the 2D (search) engines between 2D (search) Engine_0 150 and 2D (search) Engine_128K−2 158.

In this description, word lines are sometimes referred to in a 2D context by a block number and a layer number. Conceptually a block exists in the Y and Z dimensions and a layer exists in the X and Y dimensions. Conceptually the block number corresponds to the column number and the layer number corresponds to a row number.

A block corresponds to memory strings from each of the 2D (search) engines. As a specific example, the memory strings coupled between GSL511 169 and SSL511 179 correspond to block number 511. As another specific example, the memory strings coupled between GSL0 160 and SSL0 170 correspond to block number 0.

A layer corresponds to floating-gate transistors from each of the memory strings of all the 2D (search) engines. As a specific example, the floating-gate transistors coupled to WL0_511 109 and WL0_0 100 are part of layer number 0. As another specific example, the floating-gate transistors coupled to WL1_511 119 are part of layer number 1. Similarly, the floating-gate transistors respectively coupled to WL2_511 129, WL126_0 180, and WL127_0 190 are respectively part of layer numbers 2, 3, 126, and 127. Layers also correspond to layers with respect to planar integrated circuit process, although a layer of floating-gate transistors corresponds to one or more planar integrated circuit process layers.

Thus, word lines are identifiable in the Z and X dimensions respectively as “WL” “<layer number>” and “<block number>”. Thus, WL0_0 100 is of layer number 0 and block number 0. WL0_511 109 is of layer number 0 and block number 511.

FIG. 1A, FIG. 1B, and FIG. 1C illustrate an example 3D (search) engine as having a particular number of 2D (search) engines, each of which has a particular number of memory strings, each of which have a particular number of IMAS data cells (each as a respective pair of series-connected floating-gate transistors). Specifically, 3D Engine 9000 has 128K 2D (search) engines, (2D (search) Engine_0 150 . . . 2D (search) Engine_128K−1 159), but some variations have less or more 2D (search) engines. Each 2D (search) engine has 512 memory strings, but some variations have less or more memory strings. Each memory string has 64 IMAS data cells (e.g., coupled to word line pairs WL0_1 and WL1_0 . . . WL126_0 and WL127_0), but some variations have less or more IMAS data cells per memory string.

Example multi-level thermometer encoding resolutions include four bits implemented using 32 3D-NAND layers, five bits using 64 3D-NAND layers, six bits using 128 3D-NAND layers, seven bits using 256 3D-NAND layers, and eight bits using 512 3D-NAND layers. Thus, for these examples, resolution increases by one bit as the number of 3D-NAND layers is doubled.

Some variations of 2D (search) engine and associated sense amplifier circuitry enable sense amplifier resolution of a single bit (e.g., match/no-match). Some variations enable sense amplifier resolution of a plurality of bits (e.g., to encode no matches, one match, or two or more matches). Some variations enable sense amplifier indications of amount of matching (e.g., degree of similarity), such as highly similar, moderately similar, or not at all similar, Some variations enable sense amplifier indications that are analog rather than digital. For example, a sense amplifier output is a monotonically increasing function based on memory string current, and the memory string current is a monotonically increasing (or decreasing) indicator of similarity between search inputs and stored features.

Some variations of 3D (search) engines enable identifying at most one feature (stored in a single memory string) as matching for a search. Some variations enable concurrently identifying at most a plurality of features (stored in a plurality of memory strings) as matching for a search. Some variations enable concurrently identifying at most one 2D (search) engine as having one or more features stored therein as matching for a search. Some variations enable concurrently identifying a plurality of 2D (search) engines each as having one or more features stored therein as matching for a search.

Some variations of 3D (search) engines enable priority encoding match indications according to predetermined 2D (search) engine priority (e.g., a predetermined 2D (search) engine is a lowest priority and a another predetermined 2D (search) engine is a highest priority). Thus, a match indication from the predetermined highest priority 2D (search) engine corresponds to a highest priority match. Further, a match indication from a predetermined second highest priority 2D (search) engine corresponds to a second highest priority match. Some variations enable priority encoding according to how many stored feature digits within a memory string match respective search input digits (e.g., zero match, one matches, two match, or three or more match). Thus, a highest priority match corresponds to a highest number of stored feature digits within a memory string matching respective search input digits, and a second highest priority match corresponds to a second highest number of stored feature digits within a memory string matching respective search input digits. Some variations enable priority encoding according to how many memory strings match within a particular 2D (search) engine (e.g., zero match, one matches, two match, or three or more match). Thus, a highest priority match corresponds to a highest number of memory strings matching within a particular 2D (search) engine, and a second highest priority march corresponds to a second highest number of memory strings matching within a particular 2D (search) engine.

Some variations enable priority encoding that identifies a single matching stored feature. Some variations enable priority encoding that identifies a plurality of matching stored features. Some variations enable priority encoding that identifies a single “best matching” stored feature, having, e.g., a highest number of stored feature digits matching a search, and the highest number is less than a maximum stored feature length. Some variations enable priority encoding that identifies a plurality of “best matching” stored features, ranked, e.g., according to number of stored feature digits matching a search for each of a plurality of stored features.

In various usage scenarios (e.g., due to features programmed into the 2D (search) engines, provided search information, and/or encodings thereof), various numbers of 2D (search) engines of a 3D (search) engine detect a match between one or more features stored in one or more of the memory strings of the 2D (search) engines and the search information provided to the 2D (search) engines of the 3D (search) engine.

In some usage scenarios, zero, one, or more memory strings of a 2D (search) engine detect matches, and sense amplifier circuitry encodes matching results as a plurality of bits. For example, the sense amplifier circuitry encodes zero memory strings matching, one memory string matching, two memory strings matching, and more than two memory strings matching as four mutually exclusive encodings. Some variations enable priority encoding according to one or more factors, such as 2D (search) engine priority, number of matching stored feature digits, number of memory strings (e.g., features).

For example, responsive to no matches from any of 2D (search) Engine_0 150 . . . 2D (search) Engine_128K−1 159, SAs 9007 provides a vector of all zeros to Page Buffer, Cache, Priority Encoder 9008. In response, Page Buffer, Cache, Priority Encoder 9008 priority encodes the all zero vector to a binary value indicating zero matches and provides the binary value via Output Matching Result(s) 9009.

Continuing with the example, responsive to a single memory string of 2D (search) Engine_0 150 detecting a match, SAs 9007 provides a vector with an LSB corresponding to 2D (search) Engine_0 150 as a one and all other bits as zeros. In response, Page Buffer, Cache, Priority Encoder 9008 encodes the vector to a non-zero binary value identifying 2D (search) Engine_0 150 as having the matching memory string.

Continuing with the example, responsive to a plurality of memory strings of 2D (search) Engine_0 150 detecting matches as well as a single memory string of 2D (search) Engine_128K−2 158 detecting a match, SAs 9007 provides a vector with a bit corresponding to 2D (search) Engine_0 150 as a one, another bit corresponding to 2D (search) Engine_128K−2 158 as a one, and all other bits as zeros. In response, Page Buffer, Cache, Priority Encoder 9008 encodes the vector to a non-zero binary value identifying 2D (search) Engine_128K−2 158 as having the highest-priority matching memory string.

In some applications, a controller activates multiple blocks of 2D (search) engines to enable searching the multiple blocks concurrently. For example, a plurality of SSL inputs is activated in a same search operation to search multiple blocks during the same search operation.

For instance, the controller activates SSL_511 and SSL_510 in a same search operation to enable searching two blocks concurrently in each of the 128K 2D (search) engines, 2D (search) Engine_0 150 . . . 2D (search) Engine_128K−2 158, and 2D (search) Engine_128K−1 159. Thus, the controller enables 3D Engine 9000 to search 2*128K blocks concurrently. Alternatively, the controller activates any two SSL inputs in a same search operation to enable searching any two blocks concurrently. For other instances, the controller activates any 4, 6, 8, 32, 64, 128, 256, or 512 SSL inputs in a same search operation to enable searching corresponding multiple blocks concurrently. For example, the controller activates all 512 SSL inputs in a same search operation. Thus, the controller enables 3D Engine 9000 to search 512 blocks concurrently, comprising 512*128K memory strings. Optionally, the controller is responsive to a control register that specifies if and to what extent multiple blocks are searched concurrently.

### 3D (Search) Engine Encoding

Searching, comparing, and/or sorting as performed by a 3D (search) engine is according to a selected feature encoding (for feature storage in memory strings of the 3D (search) engine) and a selected search encoding (for searching performed by the memory strings). The feature and search encodings are selected in conjunction with each other, as matching performed by the memory strings is in the context of the encoding selected for the feature storage.

Example encodings usable in 3D (search) engines for storing features and/or performing searches include multi-level thermometer encoding, such as usable with MLC, TLC, QLC, and/or any type of multi-bit NAND encoding such that a memory device is enabled to represent more than two mutually exclusive states.

3D (search) Engine Multi-Level Thermometer Encoding

In multi-level thermometer encoding, an N-bit binary value (either a feature or a search) is encoded in a 2\hat{ }N bit field. The encoding produces two contiguous fields of bits. Each of the contiguous fields is a repeat of either a one or a zero. Thus, 2\hat{ }N−1 is encoded as a single leading zero and the remainder all ones. The number of ones is equal to the value being encoded. As a special case, a zero is encoded as all zeros. Thus, the most-significant bit is always zero. Therefore, in some variations, the most-significant bit is not implemented.

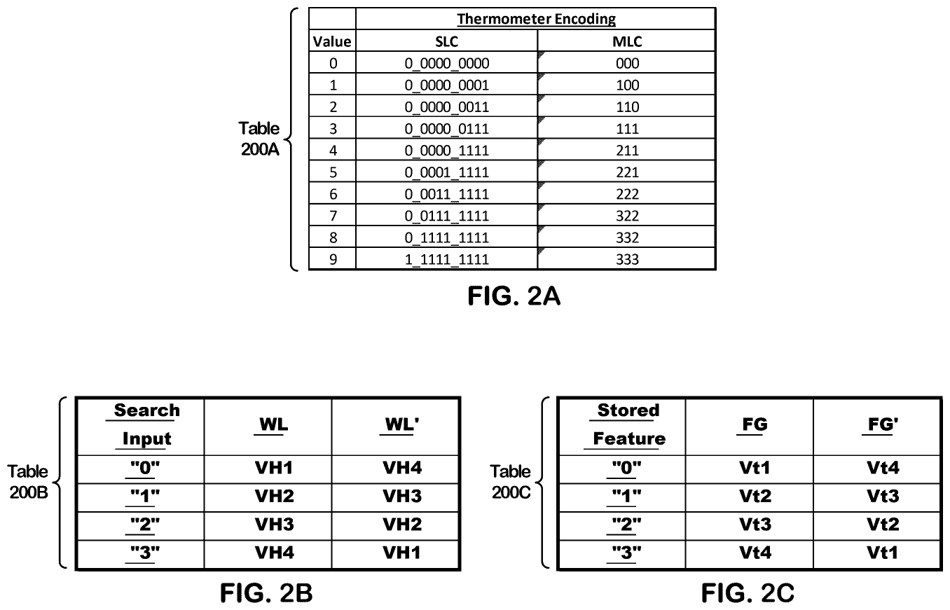

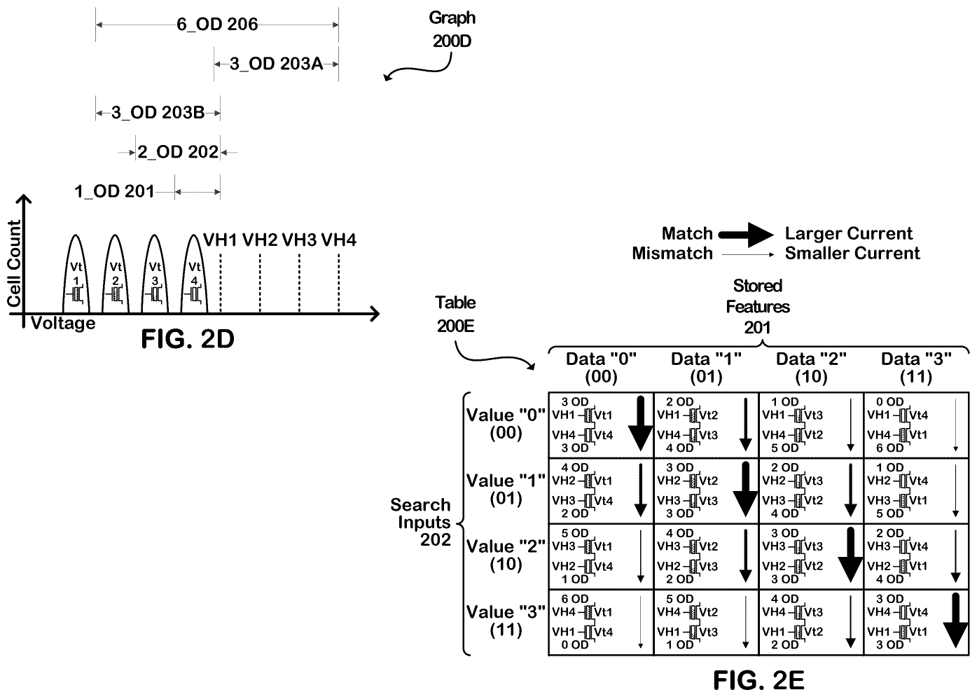

FIG. 2A, FIG. 2B, FIG. 2C, FIG. 2D, and FIG. 2E collectively illustrate an example multi-level thermometer encoding for a 3D (search) engine using Multi-Level Cell (MLC) technology.

More specifically, FIG. 2A illustrates an example multi-level thermometer encoding for a 3D (search) engine enabled, using MLC technology, to store features having ten quantized values from zero (“0”) to nine (“9”) and to search among the stored features for matches to values from zero (“0”) to nine (“9”). Table 200A includes a first column for values of “0” to “9”, a second column for an example (single-level) SLC thermometer encoding of nine SLC digits, and a third column for an example (multi-level) MLC thermometer encoding of three MLC digits. Each digit of the MLC encoding is implemented, e.g., with a corresponding MLC-based IMAS cell. For comparison, implementing the ten quantized values for storing and searching uses 9 IMAS cells for SLC-based technology and 3 IMAS cells for MLC-based technology.

FIG. 2B illustrates an example mapping of search inputs (e.g., all or any portions of Search Inputs 9006 of FIG. 1A) to corresponding pairs of word line voltages (e.g., as produced by Word Line Encoder 9005 of FIG. 1A), in accordance with the MLC encoding illustrated in FIG. 2A. Table 200B includes a first column for search inputs (e.g., digits of the MLC column of FIG. 2A) from “0” to “3”, and second and third columns for example word line voltages (WL and WL′) for pairs of devices in IMAS cells. There are four WL voltages, VH1-VH4.

FIG. 2C illustrates an example mapping of stored features (e.g., as stored in pairs of floating-gate transistors of IMAS cells of Memory Strings 9030 of FIG. 1A) to corresponding pairs of threshold voltages of the pairs of floating-gate transistors, in accordance with FIGS. 2A-2B. Table 200C includes a first column for stored features from (e.g., digits of the MLC column of FIG. 2A) “0” to “3”, and second and third columns for example threshold voltages (FG and FG′) for the pairs of floating-gate transistors. There are four threshold voltages, Vt1-Vt4, corresponding to an example of the MLC technology.

FIG. 2D illustrates example threshold voltages (stored features), word line voltages (search inputs), and overdrive amounts, in accordance with FIGS. 2A-2C. Graph 200D indicates specific WL versus Vt voltages and associated overdrive amounts. An overdrive amount is representative of similarity between a search input and a stored feature. A greater overdrive amount corresponds to a greater similarity, and a lesser overdrive amount corresponds to a lesser similarity. Overdrive amounts above “3×” (e.g., “4×”, “5×”, and “6×”) are monotonically increasing and similar to each other, due to operation in a saturation current region. An example of a “6×” overdrive is 6_OD 206, where a WL voltage of VH4 overdrives a Vt1 threshold voltage by a relative factor of 6. An example of a “3×” overdrive is 3_OD 203A, where a WL voltage of VH4 overdrives a Vt4 voltage by a relative factor of 3. Another example of a “3×” overdrive is 3_OD 203B, where a WL voltage of VH1 overdrives a Vt1 voltage by a relative factor of 3. An example of a “2×” overdrive is 2_OD 202, where a WL voltage of VH1 overdrives a Vt2 threshold voltage by a factor of 2. An example of a “1×” overdrive is 1 OD 201, where a WL voltage of VH1 overdrives a Vt3 threshold voltage by a factor of 1.

FIG. 2E illustrates example IMAS cell current capabilities in dependence on search input and stored features, in accordance with FIGS. 2A-2D. Table 200E is organized in two dimensions, rows corresponding to Search Inputs 202 and columns corresponding to Stored Features 201. Each entry in Table 200E indicates current capability of an IMAS cell when configured (e.g., via programming a pair of threshold voltages) to store a particular data value (e.g., one of Data “0” to “3”) and is searched via application of a pair of WL voltages (e.g., on of Value “0” to “3”). Each entry in the table indicates, for a respective IMAS cell and devices thereof, programmed Vt voltages and applied WL voltages, overdrive for each device of the IMAS cell, as well as resultant overdrive of the IMAS cell. Since the devices in each IMAS cell are in series, the lowest one of the two overdrive values dominates the resultant overdrive of the IMAS cell.

Some specific examples follow. A WL voltage corresponding to Value “0” applied to an IMAS cell storing data “3” results in a 6× overdrive (e.g., as indicated by 6_OD 206 of FIG. 2D) for the lower device of the corresponding IMAS cell. A WL voltage corresponding to Value “0” applied to an IMAS cell storing data “0” results in a 3× overdrive (e.g., as indicated by 3_OD 203A of FIG. 2D) for the lower device of the corresponding IMAS cell. A WL voltage corresponding to Value “0” applied to an IMAS cell storing data “0” results in a 3× overdrive (e.g., as indicated by 3_OD 203B of FIG. 2D) for the upper device of the corresponding IMAS cell. A WL voltage corresponding to Value “0” applied to an IMAS cell storing data “1” results in a 2× overdrive (e.g., as indicated by 2_OD 202 of FIG. 2D) for the upper device of the corresponding IMAS cell. A WL voltage corresponding to Value “0” applied to an IMAS cell storing data “2” results in a 1× overdrive (e.g., as indicated by 1_OD 201 of FIG. 2D) for the upper device of the corresponding IMAS cell. Other specific examples of resultant overdrive values are illustrated by Table 200E.

Thus, an IMAS cell compatible with multi-level thermometer encoding for a 3D (search) engine using Multi-Level Cell (MLC) technology has a pair of series-connected floating-gate memory devices. Each memory device is enabled to operate with one of four threshold voltages (e.g., VT1-VT4). The pair of threshold voltages that the floating-gate memory devices are operated at collectively represent one of four distinct states, each in turn representing a digit of a stored feature value. Each floating-gate memory device is responsive to a word line, operable in pairs corresponding to pairs of the floating-gate memory devices of the IMAS cells. Each word line is controllable to one of a plurality of control voltages, including four feature search control voltages (VH1-VH4). The word lines are operated in pairs corresponding to the pairs of floating-gate memory devices of the IMAS cells. The pair of control voltages that the word lines are controlled to collectively represent one of four distinct states, each in turn representing a digit of a searched feature value.

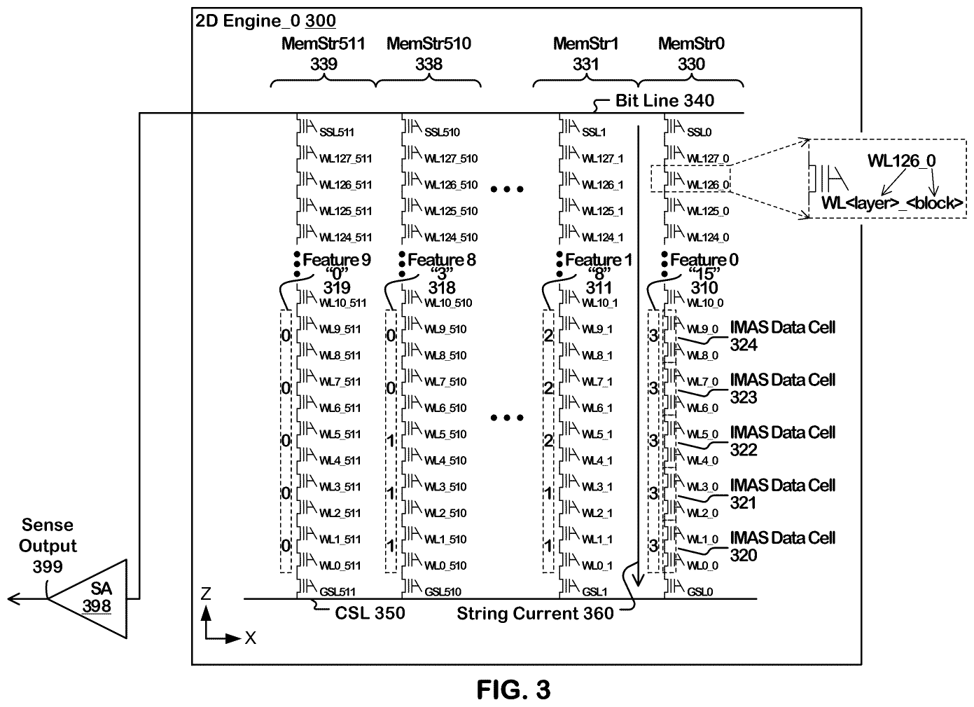

FIG. 3 illustrates an MLC-based 2D (search) Engine_0 300 (an example implementation and/or usage example of, e.g., Engine_0 150 of FIG. 1B) in the context of portions of FIG. 1A and FIG. 1B. Numerous word lines are illustrated and identified in the aforementioned “WL” “<layer number>” and “<block number>” scheme, as illustrated by the icon near WL126_0. 2D (search) Engine_0 300 comprises 512 memory strings. For clarity, four of the memory strings are illustrated (MemStr0 330, MemStr1 331, MemStr510 338, and MemStr511 339). The floating-gate transistors of each of the memory strings are arranged and operated in pairs, such as corresponding to FG and FG′ of FIG. 2C. Examples of the pairs are IMAS Data Cells 320-324. The word lines are arranged and operated in pairs, such as corresponding to WL and WL′ of FIG. 2B. Each of the even-layer-numbered word lines is coupled to the control gate of one of the floating-gate transistors of the pairs. E.g., WL0_0, WL0_1 . . . WL0_510, and WL0_511 of layer 0 are each coupled to a respective one of the pairs, as are WL2_0 . . . WL2_511 of layer 2, and so forth, to WL126_0 . . . WL126_511 of layer 126. Further, each of the odd-layer-number word lines are coupled to the control gate of the other one of the floating-gate transistors of the pairs. E.g., WL1_0, WL1_1 . . . WL1_510, and WL1_511 of layer 1 are coupled respectively to the other floating-gate transistors of the pairs that WL0_0, WL0_1 . . . WL0_510, and WL0_511 of layer 0 are respectively coupled to. Each memory string has two terminals, one for bit line coupling, and one for CSL coupling. As a specific example, the “upper” terminal of MemStr511 339 is coupled to Bit Line 340 at the source/drain of the control transistor controlled by SSL511; the “lower” terminal of MemStr511 339 is coupled to CSL 350 at the source/drain of the control transistor controlled by GSL511.

FIG. 3 also illustrates a specific usage example of a 2D (search) engine. Each memory string is usable to store one or more features. Thus, the 512 memory strings of 2D (search) Engine_0 300 are collectively usable to store up to 512 features if one feature is stored per memory string. Four example features are illustrated as Feature 0 “15” 310, Feature 1 “8” 331, Feature 8 “3” 318, and Feature 9 “0” 319. Each feature is five digits and is storable using five IMAS cells, one for each digit. Thus, each of the pairs of floating-gate transistors is usable to store a single digit of one of the features. There are 64 pairs of floating-gate transistors in each of the memory strings. Thus, each of the memory strings is usable to store a feature of up to 64 digits, or any number of features up to 64 digits total.

Each memory string is usable to compare the feature stored therein with a search input supplied via the word lines coupled to the memory string. Each floating-gate transistor of the memory string is responsive to word line voltage according to the feature digit stored by the floating-gate transistor (e.g., the threshold voltage of the floating-gate transistor configured by programming). For example, operated in pairs, a pair of the floating-gate transistors indicates a match to a search input provided to the pair of floating-gate transistors via a pair of word lines via a match-found impedance (e.g., a relatively low impedance). The pair indicates lack of a match via a no-match-found impedance (e.g., a relatively high impedance). Thus, across an entirety of a memory string, responsive to all pairs of floating-gate transistor stored feature digits matching a multi-digit search input as provided via corresponding pairs of word lines, the entirety of the memory string indicates a corresponding memory string match-found impedance. Responsive to less than all pairs matching, the entirety of the memory string indicates a corresponding memory string impedance that is greater than the memory string match-found impedance. Responsive to no pairs matching, the entirety of the memory string indicates a corresponding memory string no-match-found impedance. In between all digits matching and no digits matching extremes, the memory string indicates a corresponding memory string impedance that monotonically decreases (increases) as correspondingly more (less) stored feature digits that match digit-for-digit compared to applied word line inputs. String Current 360 indicates current flow in the memory string as based on the indicated memory string impedance.

For example, MemStr0 330 is coupled to BL_0 340 via activation of SSL0 and coupled to CSL 350 via activation of GSL0. Feature 0 “15” 310 stored in MemStr0 330 is programmed to all “3” digits, one digit in each of IMAS Data Cells 320-324.

Consider first and second operating scenarios with respect to the example, with all word line pars of MemStr0 330 not coupled to Feature 0 “15” 310 indicating “pass” e.g., Vpass, so that only Feature 0 “15” 310 affects impedance of MemStr0 330. In the first operating scenario, all word line pairs coupled to Feature 0 “15” 310 of MemStr0 330 (WL0_0, WL1_0 . . . WL9_0) indicate in pairs a search for “3” digits. In response, all floating-gate transistor pairs of Feature 0 “15” 310, indicate the match-found impedance. Thus, MemStr0 330 overall indicates an impedance that is equal to the memory string match-found impedance. SA 398 senses that the impedance is the memory string match-found impedance and indicates, via Sense Output 399, that there is a match between the word line pairs and Feature 0 “15” 310.

In the second operating scenario, the word line pair coupled to IMAS Data Cell 320 (WL1_0 and WL0_0) indicates a search for a “1” digit and the remainder of the word line pairs coupled to MemStr0 330 (WL1_0, WL1_0 . . . WL8_0, WL9_0) indicate in pairs a search for “3” digits. In response, all floating-gate transistor pairs of Feature 0 “15” 310, except for the pair of IMAS Data Cell 320, indicate the match-found impedance. The pair of IMAS Data Cell 320 indicates the no-match-found impedance (since there is no match between the word line search input and the stored feature digit). Thus, MemStr0 330 overall indicates an impedance that is greater than the memory string match-found impedance. SA 398 senses that the impedance is greater than the memory string match-found impedance and indicates, via Sense Output 399, that there is not a match between the word line pairs and Feature 0 “15” 310.

SA 398 performs the sensing and generates Sense Output 399, e.g., by detecting a voltage change greater than (or lesser than) a predetermined sense threshold on BL_0 340 within a sensing time interval. In some variations, the voltage change is due to MemStr0 330 discharging a precharged value on BL_0 340 in accordance with the indicated memory string impedance. Responsive to the first operating scenario, where the impedance is greater than the memory string match-found impedance, BL_0 340 is discharged by MemStr0 330 more slowly than compared to the second operating scenario, where the impedance is equal to the memory string match-found impedance. The sense threshold and/or the sensing time interval are set to enable distinguishing between the match-found and other than the match-found impedance based on sense speed (e.g., engine bandwidth and/or latency) and noise immunity (e.g., engine resilience).

For either the first or the second operating scenarios, and continuing in the context of FIG. 1A, FIG. 1B, and FIG. 1C, Sense Output 399 is provided to Page Buffer, Cache, Priority Encoder 9008 along with corresponding sense amplifier information of the other 2D engines. Page Buffer, Cache, Priority Encoder 9008 buffers, caches, and/or priority encodes Sense Output 399 in the context of the entirety of the 2D engine sense outputs.

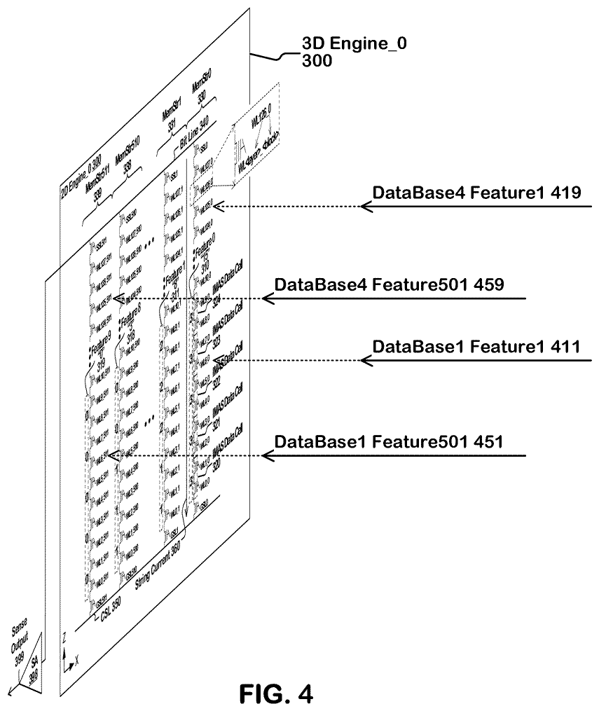

FIG. 4 illustrates usage examples for a 3D (search) engine using Multi-Level Cell (MLC) technology, e.g., 2D (search) Engine_0 300 of FIG. 3.

As illustrated in FIG. 4, 2D (search) Engine_0 300 provides for 16 values, zero (“0”) to (“15”), with 501 memory strings (e.g., corresponding to SSL0 . . . SSL500). There are ten WL inputs (five pairs) for each feature (e.g., WL0_block . . . WL9_block). There are ten series-connected transistors in each of 5 MLC-based IMAS cells to store each feature. Unselected WLs are driven with a Vpass voltage. A 96-layer implementation is enabled to store at least four databases, each using 10 WLs (e.g., 10 layers). A high similarity between a search input and a stored feature results in a high string current. A low similarity between a search input and a stored feature results in a low string current. A BL page buffer collects all string currents for features 1 to 501. Search amongst a plurality of databases (e.g., four databases) is performed, e.g., by applying a search from a first database to a first subset of the WLs (e.g., WL0_block . . . WL9_block, as indicated by arrow DataBase1 Feature1 411 and arrow DataBase1 Feature501 451), and by applying Vpass to other WLs and collecting search results. The search is further performed, e.g., by applying a search from a second database to a second subset of the WLs (e.g., WL10_block . . . WL19_block) and so forth to a last set of WLs (e.g., WL80_block . . . WL89_block, as indicated by arrow DataBase4 Feature1 419 and arrow DataBase4 Feature501 459).

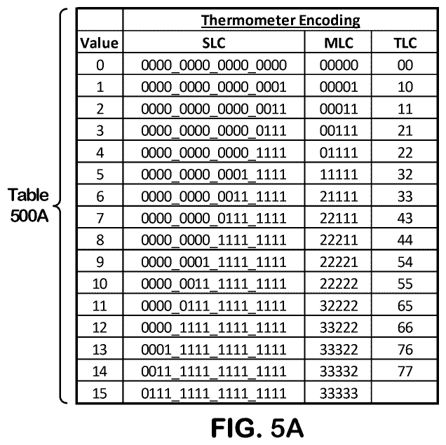

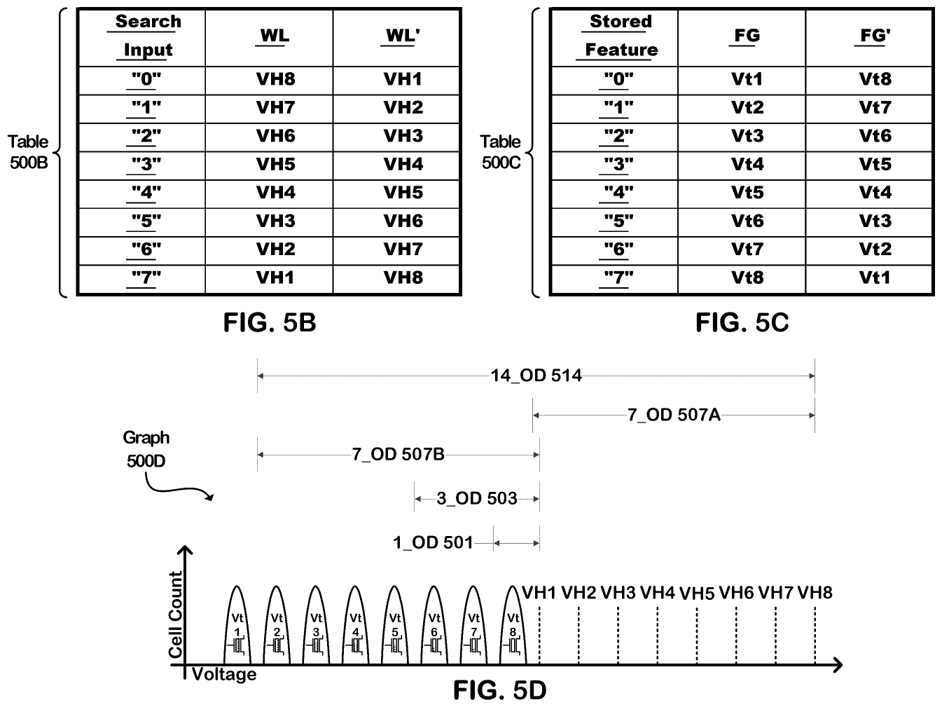

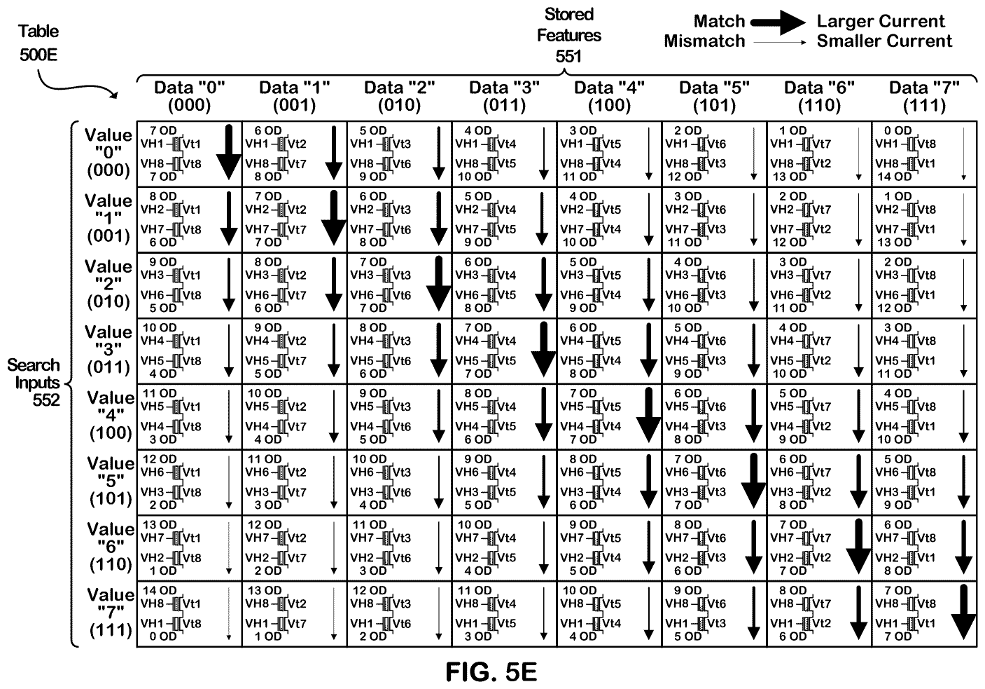

FIG. 5A, FIG. 5B, FIG. 5C, FIG. 5D, and FIG. 5E collectively illustrate an example multi-level thermometer encoding for a 3D (search) engine using Tri-Level Cell (TLC) technology.

More specifically, FIG. 5A illustrates an example multi-level thermometer encoding for a 3D (search) engine enabled, using TLC technology, to store features having 15 quantized values from zero (“0”) to fourteen (“14”) and to search among the stored features for matches to values from zero (“0”) to fourteen (“14”). Table 500A includes a first column for values of “0” to “15”, a second column for an example (single-level) SLC thermometer encoding of 16 SLC digits, a second column for an example (multi-level) MLC thermometer encoding of five MLC digits, and a fourth column for an example (tri-level) TLC thermometer encoding of two TLC digits. Each digit of the TLC encoding is implemented, e.g., with a corresponding TLC-based IMAS cell. For comparison, implementing 16 quantized values for storing and searching uses 16 IMAS cells for SLC-based technology and 5 IMAS cells for MLC-based technology, while implementing the 15 quantized values for storing and searching uses 2 IMAS cells for TLC-based technology.

FIG. 5B illustrates an example mapping of search inputs (e.g., all or any portions of Search Inputs 9006 of FIG. 1A) to corresponding pairs of word line voltages (e.g., as produced by Word Line Encoder 9005 of FIG. 1A), in accordance with FIG. 5A. Table 500B includes a first column for search inputs (e.g., digits of the TLC column of FIG. 5A) from “0” to “7”, and second and third columns for example word line voltages (WL and WL′) for pairs of devices in IMAS cells. There are eight WL voltages, VH1-VH7.

FIG. 5C illustrates an example mapping of stored features (e.g., as stored in pairs of floating-gate transistors of IMAS cells of Memory Strings 9030 of FIG. 1A) to corresponding pairs of threshold voltages of the pairs of floating-gate transistors, in accordance with FIGS. 5A-5B. Table 500C includes a first column for stored features from (e.g., digits of the TLC column of FIG. 5A) “0” to “7”, and second and third columns for example threshold voltages (FG and FG′) for the pairs of floating-gate transistors. There are eight threshold voltages, Vt1-Vt8, corresponding to an example of the TLC technology.

FIG. 5D illustrates example threshold voltages (stored features), word line voltages (search inputs), and overdrive amounts, in accordance with FIGS. 5A-5C. Graph 500D indicates specific WL versus Vt voltages and associated overdrive amounts. As in FIG. 5D, overdrive amounts above “3×” (e.g., “4×”, “5×”, and so forth up to “14×”) are monotonically increasing and similar to each other, due to operation in a saturation current region. An example of a “14×” overdrive is 14_OD 514, where a WL voltage of VH8 overdrives a Vt1 threshold voltage by a relative factor of 14. An example of a “7×” overdrive is 7_OD 507A, where a WL voltage of VH4 overdrives a Vt8 voltage by a relative factor of 7. Another example of a “7×” overdrive is 7_OD 507B, where a WL voltage of VH1 overdrives a Vt1 voltage by a relative factor of 7. An example of a “3×” overdrive is 3_OD 503, where a WL voltage of VH1 overdrives a Vt5 threshold voltage by a factor of 3. An example of a “1×” overdrive is 1_OD 501, where a WL voltage of VH1 overdrives a Vt7 threshold voltage by a factor of 1.

FIG. 5E illustrates example IMAS cell current capabilities in dependence on search input and stored features, in accordance with FIGS. 5A-5D. Table 500E is organized in two dimensions, rows corresponding to Search Inputs 552 and columns corresponding to Stored Features 551. Each entry in Table 500E indicates current capability of an IMAS cell when configured (e.g., via programming a pair of threshold voltages) to store a particular data value (e.g., one of Data “0” to “7”) and is searched via application of a pair of WL voltages (e.g., on of Value “0” to “7”). Each entry in the table indicates, for a respective IMAS cell and devices thereof, programmed Vt voltages and applied WL voltages, overdrive for each device of the IMAS cell, as well as resultant overdrive of the IMAS cell. Since the devices in each IMAS cell are in series, the lowest one of the two overdrive values dominates the resultant overdrive of the IMAS cell.

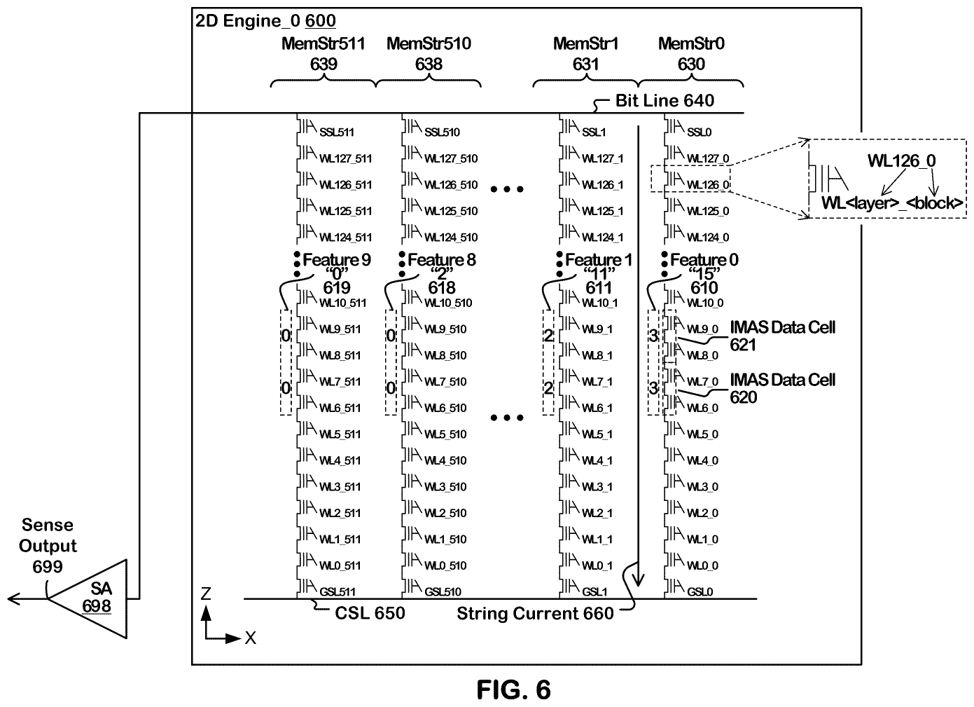

FIG. 6 illustrates a TLC-based 2D (search) Engine_0 600 (an example implementation and/or usage example of, e.g., Engine_0 150 of FIG. 1B) in the context of portions of FIG. 1A and FIG. 1B. Numerous word lines are illustrated and identified in the aforementioned “WL” “<layer number>” and “<block number>” scheme, as illustrated by the icon near WL126_0. 2D (search) Engine_0 600 comprises 512 memory strings. For clarity, four of the memory strings are illustrated (MemStr0 630, MemStr1 631, MemStr510 638, and MemStr511 639). The floating-gate transistors of each of the memory strings are arranged and operated in pairs, such as corresponding to FG and FG′ of FIG. 5C. Examples of the pairs are IMAS Data Cells 620 and 621. The word lines are arranged and operated in pairs, such as corresponding to WL and WL′ of FIG. 5B. Each of the even-layer-numbered word lines is coupled to the control gate of one of the floating-gate transistors of the pairs. E.g., WL0_0, WL0_1 . . . WL0_510, and WL0_511 of layer 0 are each coupled to a respective one of the pairs, as are WL2_0 . . . WL2_511 of layer 2, and so forth, to WL126_0 . . . WL126_511 of layer 126. Further, each of the odd-layer-number word lines are coupled to the control gate of the other one of the floating-gate transistors of the pairs. E.g., WL1_0, WL1_1 . . . WL1_510, and WL1_511 of layer 1 are coupled respectively to the other floating-gate transistors of the pairs that WL0_0, WL0_1 . . . WL0_510, and WL0_511 of layer 0 are respectively coupled to. Each memory string has two terminals, one for bit line coupling, and one for CSL coupling. As a specific example, the “upper” terminal of MemStr511 639 is coupled to Bit Line 640 at the source/drain of the control transistor controlled by SSL511; the “lower” terminal of MemStr511 639 is coupled to CSL 650 at the source/drain of the control transistor controlled by GSL511.

FIG. 6 also illustrates a specific usage example of a 2D (search) engine. Each memory string is usable to store one or more features. Thus, the 512 memory strings of 2D (search) Engine_0 600 are collectively usable to store up to 512 features if one feature is stored per memory string. Four example features are illustrated as Feature 0 “15” 610, Feature 1 “8” 631, Feature 8 “3” 618, and Feature 9 “0” 619. Each feature is two digits and is storable using two IMAS cells, one for each digit. Thus, each of the pairs of floating-gate transistors is usable to store a single digit of one of the features. There are 64 pairs of floating-gate transistors in each of the memory strings. Thus, each of the memory strings is usable to store a feature of up to 64 digits, or any number of features up to 64 digits total.

As in FIG. 4E, each memory string is usable to compare the feature stored therein with a search input supplied via the word lines coupled to the memory string. Each floating-gate transistor of the memory string is responsive to word line voltage according to the feature digit stored by the floating-gate transistor (e.g., the threshold voltage of the floating-gate transistor configured by programming). For example, operated in pairs, a pair of the floating-gate transistors indicates a match to a search input provided to the pair of floating-gate transistors via a pair of word lines via a match-found impedance (e.g., a relatively low impedance). The pair indicates lack of a match via a no-match-found impedance (e.g., a relatively high impedance). Thus, across an entirety of a memory string, responsive to all pairs of floating-gate transistor stored feature digits matching a multi-digit search input as provided via corresponding pairs of word lines, the entirety of the memory string indicates a corresponding memory string match-found impedance. Responsive to less than all pairs matching, the entirety of the memory string indicates a corresponding memory string impedance that is greater than the memory string match-found impedance. Responsive to no pairs matching, the entirety of the memory string indicates a corresponding memory string no-match-found impedance. In between all digits matching and no digits matching extremes, the memory string indicates a corresponding memory string impedance that monotonically decreases (increases) as correspondingly more (less) stored feature digits that match digit-for-digit compared to applied word line inputs. String Current 660 indicates current flow in the memory string as based on the indicated memory string impedance.

For example, MemStr0 630 is coupled to BL_0 640 via activation of SSL0 and coupled to CSL 650 via activation of GSL0. Feature 0 “15” 610 stored in MemStr0 630 is programmed to all “3” digits, one digit in each of IMAS Data Cells 620-621.

Consider first and second operating scenarios with respect to the example, with all word line pars of MemStr0 630 not coupled to Feature 0 “15” 610 indicating “pass” e.g., Vpass, so that only Feature 0 “15” 610 affects impedance of MemStr0 630. In the first operating scenario, all word line pairs coupled to Feature 0 “15” 610 of MemStr0 630 (WL0_0, WL1_0 . . . WL9_0) indicate in pairs a search for “3” digits. In response, all floating-gate transistor pairs of Feature 0 “15” 610 indicate the match-found impedance. Thus, MemStr0 630 overall indicates an impedance that is equal to the memory string match-found impedance. SA 698 senses that the impedance is the memory string match-found impedance and indicates, via Sense Output 699, that there is a match between the word line pairs and Feature 0 “15” 610.

In the second operating scenario, the word line pair coupled to IMAS Data Cell 620 (WL7_0 and WL6_0) indicates a search for a “1” digit and the word line pair coupled to IMAS Data Cell 621 (WL9_0 and WL8_0) indicates a search for a “3” digit. In response, the floating-gate transistor pair of IMAS Data Cell 620 indicates the match-not-found impedance (since there is no match between the word line search input and the stored feature digit). The floating-gate transistor pair of IMAS Data Cell 621 indicates the match-found impedance. Thus, MemStr0 630 overall indicates an impedance that is greater than the memory string match-found impedance. SA 698 senses that the impedance is greater than the memory string match-found impedance and indicates, via Sense Output 699, that there is not a match between the word line pairs and Feature 0 “15” 610.

SA 698 performs the sensing and generates Sense Output 699, e.g., by detecting a voltage change greater than (or lesser than) a predetermined sense threshold on BL_0 640 within a sensing time interval. In some variations, the voltage change is due to MemStr0 630 discharging a precharged value on BL_0 640 in accordance with the indicated memory string impedance. Responsive to the first operating scenario, where the impedance is greater than the memory string match-found impedance, BL_0 640 is discharged by MemStr0 630 more slowly than compared to the second operating scenario, where the impedance is equal to the memory string match-found impedance. The sense threshold and/or the sensing time interval are set to enable distinguishing between the match-found and other than the match-found impedance based on sense speed (e.g., engine bandwidth and/or latency) and noise immunity (e.g., engine resilience).

For either the first or the second operating scenarios, and continuing in the context of FIG. 1A, FIG. 1B, and FIG. 1C, Sense Output 699 is provided to Page Buffer, Cache, Priority Encoder 9008 along with corresponding sense amplifier information of the other 2D engines. Page Buffer, Cache, Priority Encoder 9008 buffers, caches, and/or priority encodes Sense Output 699 in the context of the entirety of the 2D engine sense outputs.

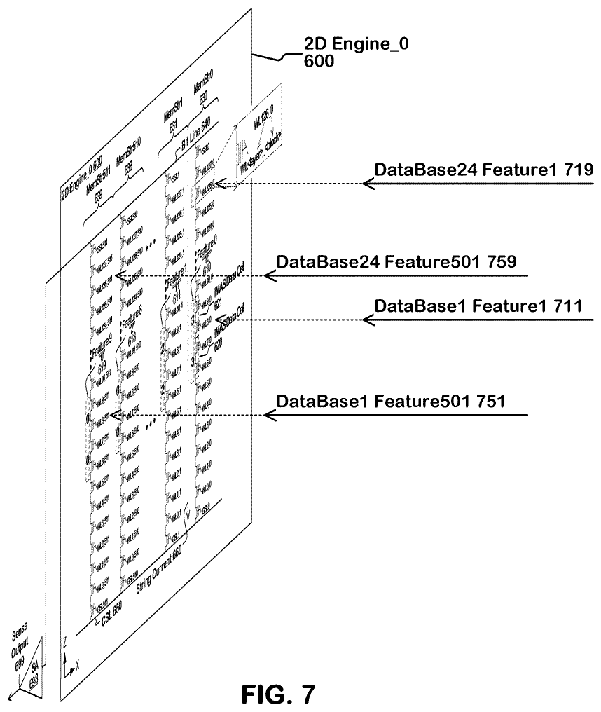

FIG. 7 illustrates usage examples for a 3D (search) engine using Tri-Level Cell (TLC) technology, e.g., 2D (search) Engine_0 600 of FIG. 6.

As illustrated in FIG. 7, 2D (search) Engine_0 600 provides for 15 values, zero (“0”) to (“14”), with 501 memory strings (e.g., SSL0 . . . SSL500). There are four WL inputs (two pairs) for each feature (e.g., WL0_block . . . WL3_block). There are four series-connected transistors in each of 2 TLC-based IMAS cells to store each feature. Unselected WLs are driven with a Vpass voltage. A 96-layer implementation is enabled to store at least 24 databases, each using 4 WLs (e.g., 4 layers). As in FIG. 4, a high similarity between a search input and a stored feature results in a high string current. A low similarity between a search input and a stored feature results in a low string current. A BL page buffer collects all string currents for features 1 to feature 501. Search amongst a plurality of databases (e.g., four databases) is performed, e.g., by applying a search from a first database to a first subset of the WLs (e.g., WL0_block . . . WL3_block, as indicated by as indicated by arrow DataBase1 Feature1 711 and arrow DataBase1 Feature501 751) and Vpass to other WLs and collecting search results. The search is further performed, e.g., by applying a search from a second database to a second subset of the WLs (e.g., WL4_block . . . WL7_block) and so forth to a last set of WLs (e.g., WL92_block . . . WL95_block, as indicated by arrow DataBase24 Feature1 719 and arrow DataBase24 Feature501 759).

### 3D (Search) Engine Operation

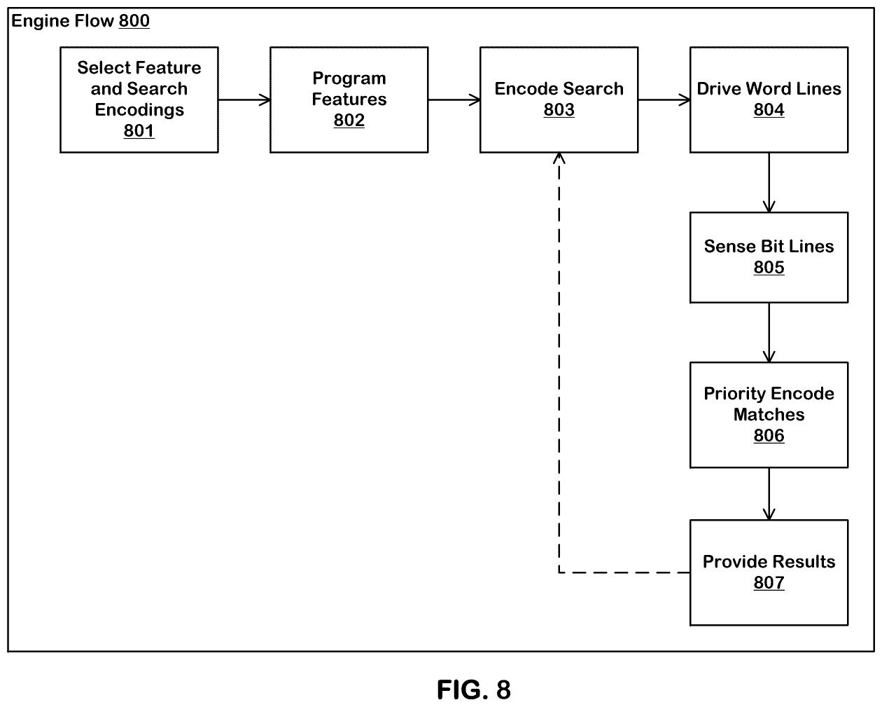

FIG. 8 illustrates an example operating flow for a 3D (search) engine (such as 3D Engine 9000 of FIG. 1A), as Engine Flow 800. Flow begins at Select Feature and Search Encodings 801. In some usage scenarios, identical encodings are used for features and searches, such as a multi-level thermometer encoding for multi-bit NAND cells (e.g., MLC, TLC, and/or QLC). Flow then proceeds to Program Features 802. The features to be searched against are programmed according to the selected feature encoding. Flow then proceeds to Encode Search 803. The search is encoded according to the selected search encoding. In some applications, a search is performed based on one or more parameters optionally including a mask and/or range information. Flow then proceeds to Drive Word Lines 804. The word lines are driven according to the search encoding. Flow then proceeds to Sense Bit Lines 805. The bit line sensing is performed by sense amplifiers. Flow then proceeds to Priority Encode Matches 806. Match indications, as provided by the sense amplifiers, are processed to determine prioritized match information (e.g., as performed by Page Buffer, Cache, Priority Encoder 9008 of FIG. 1A). Flow then proceeds to Provide Results 807. The results are provided, for example, to a host agent (e.g., as Output Matching Result(s) 9009 of FIG. 1A). Flow then optionally proceeds back to encode a next search (Encode Search 803).

### 3D (Search) Engine Device and Appliance

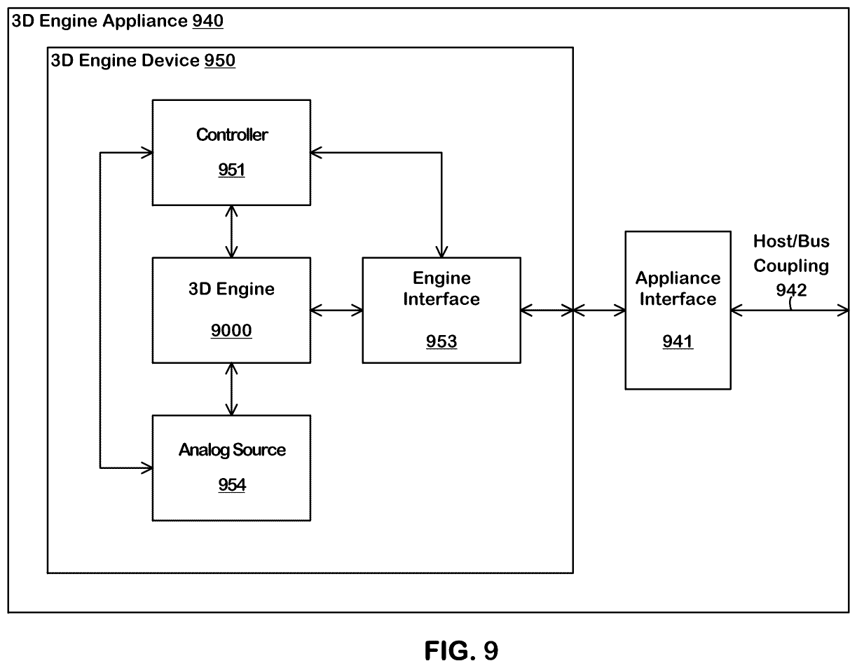

FIG. 9 illustrates an example 3D engine appliance comprising an example 3D engine device, respectively as 3D Engine Appliance 940 and 3D Engine Device 950.

3D Engine Appliance 940 comprises one or more instances of 3D engine devices, for clarity illustrated as a single device, 3D Engine Device 950, as well as Appliance Interface 941.

3D Engine Device 950 comprises 3D Engine 9000 (e.g., as illustrated and described with respect to FIGS. 1A-1C). 3D Engine Device 950 further comprises Controller 951, Engine Interface 953, and Analog Source 954. Conceptually, elements of 3D Engine Device 950 and/or 3D Engine Appliance 940 (other than 3D Engine 9000) serve to provide 3D Engine 9000 with Features 9001 and Searches 9002 from a host, and to return to the host Result(s) 9099.

Controller 951 is enabled to provide overall control of operations of and between various hardware circuitry blocks of 3D Engine Device 950. For example, Controller 951 coordinates operation of Engine Interface 953 with 3D Engine 9000. For another example, Controller 951 coordinates operation of Analog Source 954 with respect to configuration information. For another example, Controller 951 optionally coordinates feature and/or search encoding as well as feature programming as directed via Engine Interface 953 and as applicable to 3D Engine 9000. For other examples, Controller 951, in various configurations, is enabled to perform operations relating to any one or more of operations 801-807 of FIG. 8.

Engine Interface 953 is enabled to interface an agent external to 3D Engine Device 950 (such as a host via Appliance Interface 941 and Host/Bus Coupling 942) to use 3D Engine 9000. Example uses are to receive commands and data, as well as to return status relating to feature and/or search encoding, feature programming, and/or search requesting.

Analog Source 954 is enabled to generate and/or provide one or more analog outputs to, e.g., memory arrays, bit line circuitry, sense amplifier circuitry, and/or word line circuitry of the 3D (search) engine memory arrays. The analog outputs comprise zero or more voltage and/or current sources (such as reference sources), for instance as generated by one or more bias circuits.

In operation, a host provides, e.g., commands for selection of feature and/or search encoding via Host/Bus Coupling 942 and Appliance Interface 941. Appliance Interface 941 then provides the commands to Engine Interface 953 and the commands are processed by 3D Engine 9000 as directed by Controller 951. Examples of other similarly processed commands include feature programming according to the selected feature encoding, and search performing according to the selected search encoding. Status or processed commands as well as results of searches are returned to the host via Host/Bus Coupling 942 and Appliance Interface 941 as provided by Controller 951 and/or 3D Engine 9000 via Engine Interface 953. In some variations of 3D Engine Device 950, Controller 951 is enabled to operate one or more 2D (search) engines of 3D Engine 9000 concurrently.

In operation, a host external to 3D Engine Appliance 940 provides feature information for 3D Engine Device 950 to program into 3D Engine 9000. Subsequently, the host provides one or more search parameters to 3D Engine Appliance 940. 3D Engine Appliance 940, via Appliance Interface 941,

Although FIG. 9 illustrates 3D Engine 9000 used in 3D Engine Device 950 in turn used in 3D Engine Appliance 940, other usage scenarios are possible. For example, various elements (e.g., integrated circuits, one or more die of a system-on-a-chip, and/or packaged die) comprise one or more 3D engine elements identical to, substantially similar to, or based on 3D Engine 9000.

Other partitions of elements, coupling between elements, and capabilities and/or capacities of elements illustrated in the figure are contemplated, as well as additional elements, according to usage requirements.

All of any portions of 3D Engine Appliance 940 or 3D Engine Device 950 are implementable as all or any portions of a System-On-a-Chip (SOC).

### 3D (Search) Engine System

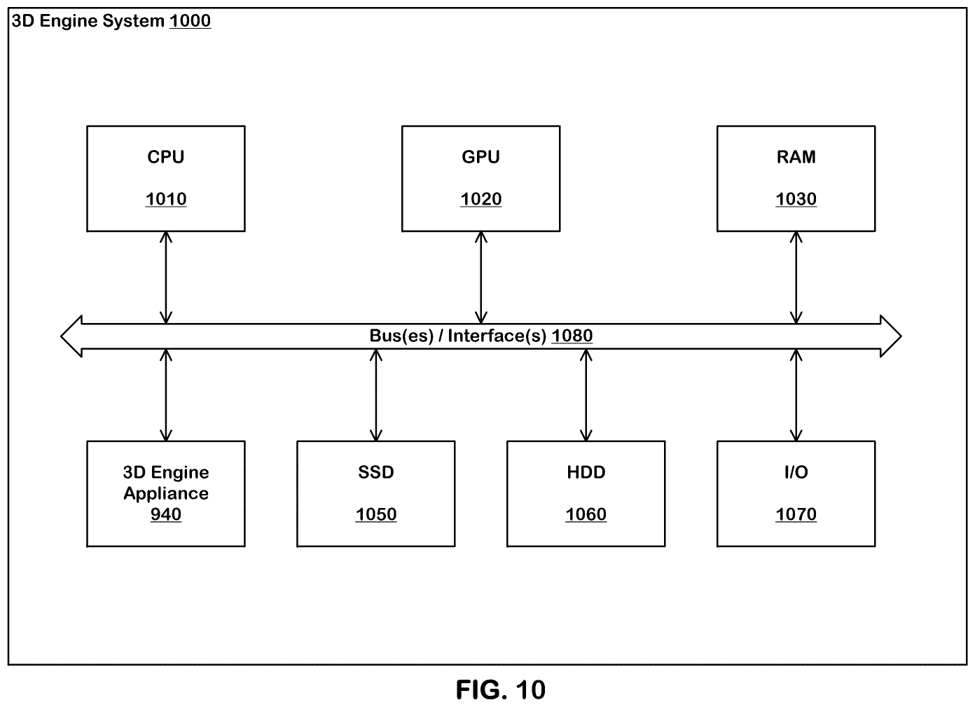

FIG. 10 illustrates an example hardware system having a 3D (search) Engine, as 3D Engine System 1000. The system comprises hardware blocks Central Processing Unit (CPU) 1010, Graphics Processing Unit (GPU) 1020, Randomly Accessible read/write Memory (RAM) 1030, 3D Engine Appliance 940 (of FIG. 9), SSD 1050, Hard Disk Drive (HDD) 1060, and Input/Output (I/O) 1070 that are coupled by hardware block Bus(es)/Interface(s) 1080.

CPU 1010 comprises one or more processing units, such as any combination of hardware units enabled to execute programmed instructions. Examples include microprocessors, Complex Instruction Set Computing (CISC) microprocessors, Reduced Instruction Set Computing (RISC) microprocessors, Very Long Instruction Word (VLIW) microprocessors, network processors, signal processors, AI processors, as well as one or more special-purpose processing devices such as an Application Specific Integrated Circuit (ASIC), a Field Programmable Gate Array (FPGA), and a Digital Signal Processor (DSP).

GPU 1020 comprises one or more processing units, such as any combination of units enabled to accelerate processing for processing that is subject to relatively highly parallel processing, such as graphics processing, signal processing, and/or AI processing.

RAM 1030 comprises one or more storage elements for storage of instructions and/or data in greater quantities than storage internal to CPU 1010 and/or GPU 1020. RAM 1030 is implementable, e.g., via volatile memory elements, such as DRAMs and/or SRAMs.

SSD 1050 comprises one or more storage elements, such as flash-based storage elements for storage of instructions and/or data optionally accessible with reduced latency compared to HDD 1060.

HDD 1060 comprises one or more storage elements, such as rotation-based magnetic and/or optical non-volatile storage elements (e.g., disks) for storage of instructions and/or data optionally in greater quantities than SSD 1050 is enabled to store.

I/O 1070 comprises elements to interface any combination of CPU 1010, GPU 1020, RAM 1030, 3D Engine Appliance 940, SSD 1050, and/or HDD 1060 to elements external to 3D Engine System 1000. Example external elements include mass storage devices, local and wide-area networks (such as the Internet), human interface components (such as keyboards, mice, and/or monitors), and other elements providing capabilities to extend and/or augment capabilities not otherwise provided by 3D Engine System 1000. I/O 1070 variously comprises one or more serial and/or parallel communication channels as well as optional protocol conversion and/or adaptation capabilities to facilitate communication between the elements coupled to it.

Bus(es)/Interface(s) 1080 enables communication between the elements coupled to it (e.g., CPU 1010, GPU 1020, RAM 1030, 3D Engine Appliance 940, SSD 1050, HDD 1060, and/or I/O 1070). Bus(es)/Interface(s) 1080 variously comprises one or more serial and/or parallel communication channels as well as optional protocol conversion and/or adaptation capabilities to facilitate communication between the elements coupled to it.

Other partitions of elements, coupling between elements, and capabilities and/or capacities of elements illustrated in the figure are contemplated, as well as additional elements, according to usage requirements.

In some circumstances, 3D Engine Appliance 940 enables reductions in processing load (e.g., on CPU 1010 and/or GPU 1020) and/or reductions in traffic on Bus(es)/Interface(s) 1080 by performing processing locally.

For example, using multi-level thermometer encoding to enable approximate matching, comparisons among large AI datasets are accomplished entirely within 3D Engine Appliance 940 once features are programmed. For another example, using multi-level thermometer encoding, optionally in conjunction with multi-bit cell NAND memories, sorting large datasets is accomplished entirely within 3D Engine Appliance 940 once features are programmed.

All of any portions of 3D Engine System 1000 are implementable as all or any portions of an SOC.

### Multi-Bit Cell NAND Multi-Level Thermometer Encoding

An example multi-level thermometer encoding for multi-bit cell NAND feature memory storage and searching is describable as a series of state transitions, such as from a lowest value representable by the example multi-level thermometer encoding to a highest representable value. Each state of the state transitions represents a particular one of the values. Each state is characterized by one or more digits having respective values.

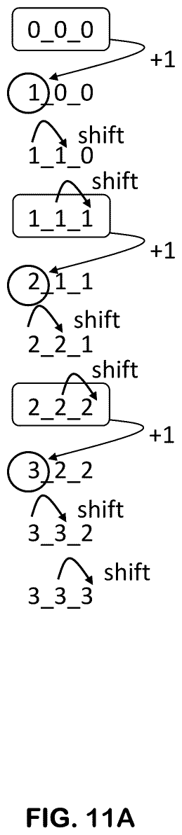

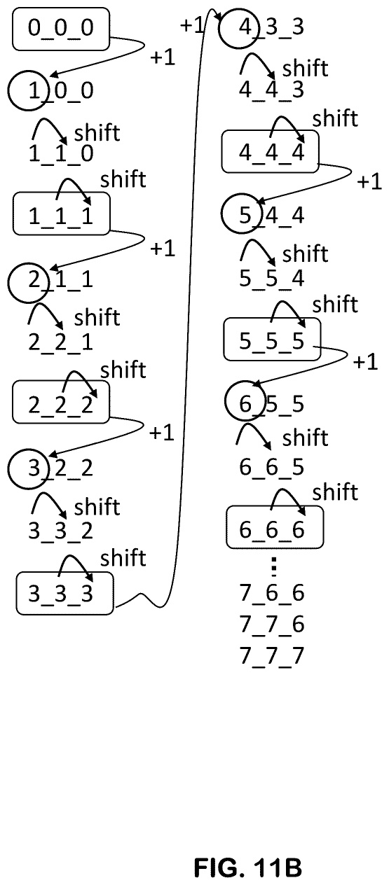

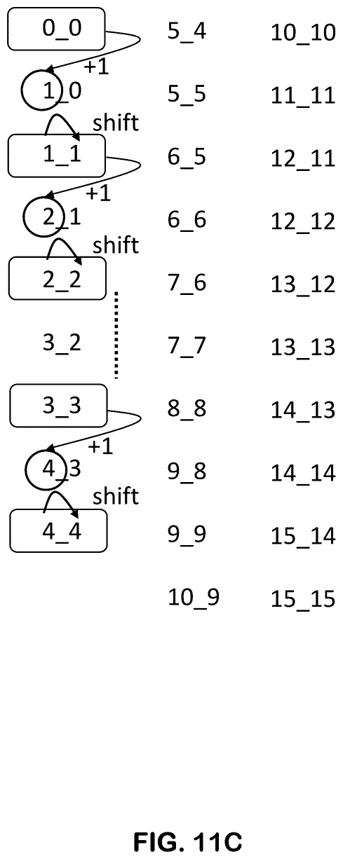

FIGS. 11A, 11B, and 11C each illustrate a respective example of a multi-level thermometer encoding, as a respective series of state transitions, for multi-bit cell NAND feature memory storing and searching. In the examples, each digit is stored in a corresponding IMAS cell having two series memory devices each enabled to represent one of a plurality of mutually exclusive states quantizable to corresponding values.

FIG. 11A illustrates an example of a multi-level thermometer encoding, as a series of state transitions, for an MLC-based IMAS cell for feature memory storage and searching. The example multi-level thermometer encoding is enabled to represent 10 values (integers from “0” to “9”) using three digits implemented in three corresponding IMAS cells. See FIGS. 2A-2E, 3, and 4 for implementation and operation of an example MLC-based multi-level thermometer encoding.

FIG. 11B illustrates an example of a multi-level thermometer encoding, as a series of state transitions, for a TLC-based IMAS cell for feature memory storage and searching. The example multi-level thermometer encoding is enabled to represent 22 values (integers from “0” to “21”) using three digits implemented in three corresponding IMAS cells. See FIGS. 5A-5E, 6, and 7 for implementation and operation of a TLC-based example multi-level thermometer encoding.

FIG. 11C illustrates an example of a multi-level thermometer encoding, as a series of state transitions, for a QLC-based IMAS cell for feature memory storage and searching. The example multi-level thermometer encoding is enabled to represent 31 values (integers from “0” to “30”) using two digits implemented in two corresponding IMAS cells. The memory devices of the IMAS cells are enabled to operate with one of sixteen threshold voltages (e.g., VT1-VT16). The word line pairs supplied to the memory devices are controlled to represent one of sixteen search input values.

### 3D (Search) Engine Additional Information

Example memory technologies applicable to memory arrays of 2D and/or 3D (search) engines as disclosed herein include floating-gate, split-gate, Silicon-Oxide-Nitride-Oxide-Silicon (SONOS), floating dot, Dynamic Random Access read/write Memory (DRAM), DRAM-like such as Two-Transistor Zero-Capacitor (2TOC), Ferroelectric Field-Effect Transistor (FeFET), and any memory technology compatible with search via word lines and bit lines. Exemplary SONOS memory technology (sometimes referred to as charge trap memory) uses an insulating layer (e.g., of silicon nitride) with traps to capture and retain charge as injected from a channel. Exemplary floating dot memory technology conceptually replaces a floating gate with a floating silicon nanodot or embeds floating silicon nanodots in a polysilicon gate. Exemplary 2TOC memory technology uses parasitic capacitance of a read transistor to store charge rather than an explicit storage capacitor. Exemplary FeFET memory technology uses permanent electrical field polarization of ferroelectric material embedded between a gate and a source-gate conduction region to store information. Example memory structures applicable to memory arrays of 3D (search) engines include 2D structures (e.g., 2D flash structures) and 3D structures (e.g., 3D flash structures). Example array architectures applicable to memory arrays of 3D (search) engines include NOR/OR-type array architectures and AND/NAND-type array architectures.

It is understood that the foregoing disclosure presents implementations, variations, embodiments, and examples in an intended illustrative sense rather than in a limiting sense. It is contemplated that modifications and combinations are discernible that will be within the spirit of the disclosure and the scope of the following claims. What is claimed is:

1. A computing system comprising:
a memory comprising
a plurality of memory strings, each coupled to a match line coupled to a sense amplifier and a source line, and each memory string comprising a plurality of series-connected devices, each having and being responsive to a configured state that is one of three or more mutually exclusive state values and a respective control input; and
a plurality of word lines, each coupled to a respective control input of the respective control inputs; and
a search encoder enabled to receive a search and drive the word lines according to a search encoding,
wherein each memory string is enabled to couple the match and the source lines via an impedance responsive to an amount of a match between the configured states of the memory string and the control inputs of the series-connected devices, and the sense amplifier is enabled to generate a respective indication of the amount of the match indicated by the impedance.

2. The computing system of claim 1, wherein the search encoding comprises a multi-level thermometer search encoding.

3. The computing system of claim 2, wherein the multi-level search encoding uses a plurality of digits each having a respective digit value that is one of N mutually exclusive digit values, and there are N mutually exclusive state values, N being an integer that is greater than 2.

4. The computing system of claim 2, wherein the word lines are operated in pairs according to the multi-level thermometer search encoding and the configured states are managed in pairs according to a multi-level thermometer feature encoding.

5. The computing system of claim 1, wherein responsive to the impedance being a match-found impedance, the respective indication of the amount of the match indicated by the impedance is a match-found indication.

6. The computing system of claim 1, wherein the series-connected devices comprise series-connected floating-gate transistors, each of the configured states corresponds to a respective threshold voltage that the series-connected floating-gate transistors are enabled to operate in accordance with, and each of the respective control inputs is coupled to a respective gate of one more of the series-connected floating-gate transistors.

7. A method comprising:
receiving a search request encoded according to a thermometer code having a plurality of search digits, each enabled to represent one of more than two distinct values;
responsive to the search request, determining whether a memory array having a plurality of In Memory Approximate Search (IMAS) cells has stored, within a subset of the IMAS cells, a feature matching the search request, each enabled to store a respective digit of the stored feature, each enabled to represent a respective one of more than two distinct values; and
indicating a result of the determining.

8. The method of claim 7, wherein each of the IMAS cells comprises a pair of floating-gate transistors in series, each operable according to more than two distinct threshold voltages, and the determining comprises applying word line voltages to control gates of the floating-gate transistors according to the more than two distinct threshold voltages.

9. The method of claim 7, wherein the search request is an encoded search request and further comprising receiving an unencoded search request and in dependence thereon producing the encoded search request.

10. The method of claim 7, wherein the indicating of the result comprises indicating a selected one of (a) a match between the search request and the stored feature matching the search request and (b) no match between the search request and any feature stored in the memory array.

11. The method of claim 10, wherein the indicating of the result comprises indicating an approximate match between the search request and the stored feature matching the search request.

12. The method of claim 7, wherein the IMAS cells correspond to at least one of a Multi-Level Cell (MLC) flash storage technology and a Tri-Level Cell (TLC) flash storage technology.

13. A computing system comprising:
interface circuitry to enable a host agent to provide a search and to receive one or more results of the search;
a plurality of memory strings each receiving a respective set of word lines having voltages determinable responsive to the search from and selected from a set of more than three word line voltage values;
a plurality of sense amplifiers each coupled to a corresponding one of the memory strings; and
priority encoder circuitry enabled to receive match indications from the sense amplifiers, and
wherein the sense amplifiers are enabled to determine, with respect to matches between feature information stored in the memory strings coupled to the sense amplifier and the word lines received by the memory strings coupled to the sense amplifier, that there are no matches and there is at least one match, and
wherein the priority encoder circuitry, based on the determinations of the sense amplifiers, is enabled to indicate at least a portion of the results as a highest priority match of any matches identified by the sense amplifiers.

14. The computing system of claim 13, further comprising a multi-level thermometer search encoder to determine the word line voltages responsive to the search.

15. The computing system of claim 13, further comprising the host agent.

16. The computing system of claim 13, wherein the priority encoder circuitry, based on the determinations of the sense amplifiers, is enabled to indicate at least a portion of the results as a second highest priority match of any matches identified by the sense amplifiers.

17. The computing system of claim 13, further comprising a multi-level thermometer feature encoder and wherein the feature information is stored in the memory strings by configuring threshold voltages of floating-gate transistors of the memory strings in dependence on encoding results of the multi-level thermometer feature encoder.

18. The computing system of claim 13, wherein a feature encoding is used to encode at least some of the feature information and a search encoding is used to encode at least a portion of the search.

19. The computing system of claim 18, wherein the feature encoding is a multi-level thermometer encoding compatible with the memory strings operating in accordance with threshold voltages set in accordance with more than two threshold voltages.

20. The computing system of claim 13, wherein the computing system is part of a System-On-a-Chip (SOC).
